(19) United States
(12) Patent Application Publication
(10) Pub. No.: US 2014/0116500 A1
(43) Pub. Date: May 1, 2014

(54) INVERTED METAMORPHIC MULTIJUNCTION SOLAR CELLS MOUNTED ON FLEXIBLE SUPPORT WITH BIFACIAL CONTACTS

(71) Applicants: Mark A. Stan, Albuquerque, NM (US); Chelsea Mackos, Albuquerque, NM (US); Paul R. Sharps, Albuquerque, NM (US); Cory Tourino, Edgewood, NM (US); Arthur Cornfeld, Sandia Park, NM (US)

(72) Inventors: Mark A. Stan, Albuquerque, NM (US); Chelsea Mackos, Albuquerque, NM (US); Paul R. Sharps, Albuquerque, NM (US); Cory Tourino, Edgewood, NM (US); Arthur Cornfeld, Sandia Park, NM (US)

(73) Assignee: Emcore Solar Power, Inc., Albuquerque, NM (US)

(21) Appl. No.: 13/831,406

(22) Filed: Mar. 14, 2013

Related U.S. Application Data
(60) Provisional application No. 61/720,595, filed on Oct. 31, 2012.

(51) Int. Cl. H01L 31/0687; H01L 31/18

(52) U.S. Cl. CPC H01L 31/06875; H01L 31/1896
USPC 136/255; 438/65

(57) ABSTRACT

A method of manufacturing a mounted solar cell by providing a first substrate; depositing on the first substrate a sequence of layers of semiconductor material to form a multijunction solar cell using an MOCVD process; depositing a metal electrode layer on its surface of the layers of semiconductor material; attaching a metallic flexible film comprising a nickel-cobalt ferrous alloy material, or a nickel iron alloy material, directly to the surface of the metal electrode layer of the semiconductor solar cell. The first substrate is removed, and an electrical interconnection member is attached to the solar cell.

### REFERENCE TO RELATED APPLICATIONS

The present nonprovisional patent application claims priority under 35 U.S.C. §119(e) from U.S. Provisional patent application having Ser. No. 61/720,595, filed on Oct. 31, 2012.

### REFERENCE TO RELATED APPLICATIONS

This application is a continuation-in-part of U.S. patent application Ser. No. 12/637,241, filed Dec. 14, 2009, which in turn is a continuation-in-part of U.S. patent application Ser. No. 11/616,596, filed Dec. 27, 2006, and Ser. No. 12/544,001, filed Aug. 19, 2009.

This application is related to co-pending U.S. patent application Ser. No. 13/604,833 filed Sep. 6, 2012, which is a continuation-in-part of U.S. patent application Ser. No. 12/637,241, filed Dec. 14, 2009, which in turn is a continuation-in-part of U.S. patent application Ser. No. 11/616,596, filed Dec. 27, 2006, and Ser. No. 12/544,001, filed Aug. 19, 2009.

This application is related to co-pending U.S. patent application Ser. No. 13/569,794 filed Aug. 9, 2012.

This application is related to co-pending U.S. patent application Ser. No. 13/560,663 filed Jul. 27, 2012.

This application is related to co-pending U.S. patent application Ser. No. 13/547,334 filed Jul. 12, 2012.

This application is related to co-pending U.S. patent application Ser. No. 13/463,069 filed May 3, 2012.

This application is related to co-pending U.S. patent application Ser. No. 13/440,331 filed Apr. 15, 2012.

This application is related to co-pending U.S. patent application Ser. No. 13/401,181 filed Feb. 21, 2012.

This application is related to co-pending U.S. patent application Ser. No. 13/315,877 filed Dec. 9, 2011.

This application is related to co-pending U.S. patent application Ser. No. 12/844,673 filed Jul. 27, 2010.

This application is related to co-pending U.S. patent application Ser. No. 12/813,408 filed Jun. 10, 2010.

This application is related to co-pending U.S. patent application Ser. No. 12/775,946 filed May 7, 2010.

This application is related to co-pending U.S. patent application Ser. No. 12/756,926, filed Apr. 8, 2010.

This application is related to co-pending U.S. patent application Ser. No. 12/716,814, filed Mar. 3, 2010.

This application is related to co-pending U.S. patent application Ser. No. 12/708,361, filed Feb. 18, 2010.

This application is related to co-pending U.S. patent application Ser. No. 12/623,134, filed Nov. 20, 2009.

This application is related to co-pending U.S. patent application Ser. No. 12/544,001, filed Aug. 19, 2009.

This application is related to U.S. patent application Ser. No. 12/537,361, filed Aug. 7, 2009, now U.S. Pat. No. 8,262,856.

This application is related to co-pending U.S. patent application Ser. Nos. 12/401,137, and 12/401,157, filed Mar. 10, 2009.

This application is related to U.S. patent application Ser. No. 12/362,201, now U.S. Pat. No. 7,960,201; Ser. No. 12/362,213; and Ser. No. 12/362,225, filed Jan. 29, 2009.

This application is related to U.S. patent application Ser. No. 12/337,014 filed Dec. 17, 2008, now U.S. Pat. No. 7,785,989.

This application is related to co-pending U.S. patent application Ser. No. 12/271,192 filed Nov. 14, 2008.

This application is related to U.S. patent application Ser. No. 12/267,812 filed Nov. 10, 2008, now U.S. Pat. No. 8,236,600.

This application is related to U.S. patent application Ser. No. 12/190,449, filed Aug. 12, 2008, now U.S. Pat. No. 7,741,146, and its divisional patent application Ser. No. 12/816,205, filed Jun. 15, 2010, now U.S. Pat. No. 8,039,291.

This application is related to U.S. patent application Ser. No. 12/187,477, filed Aug. 7, 2008, now U.S. Pat. No. 8,263,853.

This application is related to co-pending U.S. patent application Ser. No. 12/218,558 and U.S. patent application Ser. No. 12/218,582 filed Jul. 16, 2008.

This application is related to co-pending U.S. patent application Ser. No. 12/123,864 filed May 20, 2008.

This application is related to co-pending U.S. patent application Ser. No. 12/023,772, filed Jan. 31, 2008.

This application is related to U.S. patent application Ser. No. 11/956,069, filed Dec. 13, 2007, and its divisional application Ser. No. 12/187,454 filed Aug. 7, 2008, now U.S. Pat. No. 7,727,795.

This application is also related to co-pending U.S. patent application Ser. Nos. 11/860,142 and 11/860,183 filed Sep. 24, 2007.

This application is also related to co-pending U.S. patent application Ser. No. 11/445,793 filed Jun. 2, 2006.

### GOVERNMENT RIGHTS STATEMENT

This invention was made with government support under Contract No. NRO 000-10-C-0285. The Government has certain rights in the invention.

### BACKGROUND OF THE INVENTION

1. Field of the Invention

The present invention relates to the field of semiconductor devices, and to fabrication processes and devices such as multijunction solar cells based on III-V semiconductor compounds including a metamorphic layer. Some embodiments of such devices are also known as inverted metamorphic multijunction solar cells.

2. Description of the Related Art

Solar power from photovoltaic cells, also called solar cells, has been predominantly provided by silicon semiconductor technology. In the past several years, however, high-volume manufacturing of III-V compound semiconductor multijunction solar cells for space applications has accelerated the development of such technology not only for use in space but also for terrestrial solar power applications. Compared to silicon, III-V compound semiconductor multijunction devices have greater energy conversion efficiencies and generally more radiation resistance, although they tend to be more complex to manufacture. Typical commercial III-V compound semiconductor multijunction solar cells have energy efficiencies that exceed 27% under one sun, air mass 0 (AM0), illumination, whereas even the most efficient silicon technologies generally reach only about 18% efficiency under comparable conditions. Under high solar concentration (e.g., 500×), commercially available III-V compound semiconductor multijunction solar cells in terrestrial applications (at AM1.5D) have energy efficiencies that exceed 44%. The higher conversion efficiency of III-V compound semiconductor solar cells compared to silicon solar cells is in part based on the ability to achieve spectral splitting of the incident radiation through the use of a plurality of photovoltaic regions with different band gap energies, and accumulating the current from each of the regions.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as payloads become more sophisticated, the power-to-weight ratio of a solar cell becomes increasingly more important, and there is increasing interest in lighter weight, “thin film” type solar cells having both high efficiency and low mass.

Typical III-V compound semiconductor solar cells are fabricated on a semiconductor wafer in vertical, multijunction structures. The individual solar cells or wafers are then disposed in horizontal arrays, with the individual solar cells connected together in an electrical series and/or parallel circuit. The shape and structure of an array, as well as the number of cells it contains, are determined in part by the desired output voltage and current.

Inverted metamorphic solar cell structures based on III-V compound semiconductor layers, such as described in M. W. Wanlass et al., Lattice Mismatched Approaches for High Performance, III-V Photovoltaic Energy Converters (Conference Proceedings of the 31^{st} IEEE Photovoltaic Specialists Conference, Jan. 3-7, 2005, IEEE Press, 2005), present an important conceptual starting point for the development of future commercial high efficiency solar cells. However, the materials and structures for a number of different layers of the cell proposed and described in such reference present a number of practical difficulties, particularly relating to the most appropriate choice of materials and fabrication steps.

### SUMMARY OF THE INVENTION

Briefly, and in general terms, the present disclosure provides a method of manufacturing a mounted solar cell comprising: providing a first substrate; depositing on the first substrate a sequence of layers of semiconductor material using an MOCVD reactor to form a multijunction solar cell; depositing a metal electrode layer on its surface of the layers of semiconductor material; attaching a metallic flexible film comprising a nickel-cobalt ferrous alloy material, or a nickel iron alloy material directly to the surface of the metal electrode layer of the semiconductor solar cell, wherein the coefficient of thermal expansion of the semiconductor body closely matches the coefficient of thermal expansion of the metallic film and the metal electrode layer; removing the first substrate; depositing and lithographically patterning a plurality of metal grid lines disposed on the top surface of the first solar subcell, including at least one metal contact pad electrically connected to said grid lines and disposed adjacent to a first peripheral edge of said first solar subcell; and attaching a discrete inter-cell electrical interconnection member to the metal contact pad.

In some embodiments, a surrogate substrate is bonded over the metallic flexible film prior to removing the first substrate.

In some embodiments, a surrogate substrate is bonded over the metallic flexible film using a temporary adhesive, and subsequently the first substrate is removed by grinding the first substrate to remove over 80% of its thickness, followed by an etching step to remove the remaining portion of the first substrate.

In some embodiments, after removing the first substrate; the present disclosure provides depositing and lithographically patterning a plurality of metal grid lines disposed on the top surface of the first solar subcell, including at least one metal contact pad electrically connected to said grid lines and disposed adjacent to a first peripheral edge of said first solar subcell; and depositing an anti-reflection coating layer over the metal grid lines and the exposed top surface of the solar cell.

In some embodiments, the first substrate has a surface area in excess of 50 square centimeters.

In some embodiments, the attaching step of the metallic film is performed by one of adhesive bonding or soldering.

In some embodiments, the adhesive bonding step utilizes Ag or C-loaded polymide/or B-stage epoxies.

In some embodiments, the soldering step utilizes AuGe, AuSn, PbSn, SnAgCu (SAC)-solders.

In some embodiments, the metallic film is a solid metallic foil.

In some embodiments, the first substrate is removed by grinding the first substrate to remove over 80% of its thickness, followed by an etching step to remove the remaining portion of the first substrate.

In some embodiments, the discrete interconnection member is a planar rectangular clip having a first end-portion welded to the metal contact layer, a second portion connected to the first end-portion and extending above the surface of the solar cell, and a third portion connected to the second portion and being serpentine in shape, and further comprising subsequently attaching a cover glass over the side of the solar cell having the metal grid lines and the attached interconnection member,

In some embodiments, further comprising welding the third portion of the metal interconnection member is welded to a terminal of opposite polarity of an adjacent solar cell to thereby form an electrical series connection.

In some embodiments, the metal electrode layer has a coefficient of thermal expansion within a range of 0 to 10 ppm per degree Kelvin different from that of the adjacent semiconductor material of the semiconductor solar cell. The metal electrode layer is a multilayer stack. Most of the metals in the stack do not fall within 10 ppm/K CTE range of the semiconductor.

In some embodiments, the metal electrode layer includes molybdenum or Kovar, or and Fe—Ni alloy suitably CTE matched to the semiconductor material.

In some embodiments, the metal electrode layer includes a sequence of layers including Ti/Au/Ag/Au or Ti/Mo/Ni/Au, among other sequences of layers in the metal electrode layer.

In some embodiments, the attaching step of the interconnection member is performed by welding.

In some embodiments, the metal interconnection member is composed of molybdenum, a nickel-cobalt ferrous alloy, or a nickel iron alloy material.

In some embodiments, the step of depositing a sequence of layers comprises forming a first subcell comprising a first semiconductor material with a first band gap and a first lattice constant; forming a second subcell comprising a second semiconductor material with a second band gap and a second lattice constant, wherein the second band gap is less than the first band gap and the second lattice constant is greater than the first lattice constant; and forming a lattice constant transition material positioned between the first subcell and the second subcell, said lattice constant transition material having a lattice constant that changes gradually from the first lattice constant to the second lattice constant.

In some embodiments, the transition material is composed of any of the Al, Ga, In, As, N, P, Sb based III-V compound semiconductors subject to the constraints of having the in-plane lattice parameter greater or equal to that of the first subcell and less than or equal to that of the second subcell, and having a band gap energy greater than that of the first subcell, and the band gap of the transition material remains constant throughout its thickness.

In some embodiments, the lattice constant transition material is composed of (InₓGa₁₋ₓ)_{y}Al_{1-y}As with 0<x<1, 0<y<1, and x and y selected such that the band gap of the transition material remains constant throughout its thickness.

In some embodiments, the lattice constant transition material is deposited using an MOCVD reactor in a process time of less than 45 minutes using precursor gases including trimethylgallium, trimethylindium, and arsine.

In some embodiments, the group III elements comprising the subcells include Al, Ga and In and the group V elements comprising the subcells include As, P, Sb, and N.

In some embodiments, the step of depositing a sequence of layers comprises forming a first subcell comprising a first semiconductor material with a first band gap and a first lattice constant; forming a second subcell comprising a second semiconductor material with a second band gap and a second lattice constant, wherein the second band gap is less than the first band; forming a grading interlayer over the second subcell, and having a third band gap greater than said second band gap, and having a lattice constant that changes gradually from the second lattice constant to a third lattice constant; and forming a third subcell comprising a third semiconductor material with a fourth band gap and a third lattice constant, wherein the fourth band gap is less than the second band gap and the third subcell is lattice mismatched with respect to the second subcell.

In another aspect, the present disclosure provides multijunction solar cell comprising a top first solar subcell having a first band gap; a middle second solar subcell disposed directly adjacent to said first subcell and having a second band gap smaller than said first band gap; a grading interlayer disposed directly adjacent to said second subcell and having a third band gap greater than second band gap; a bottom third solar subcell disposed and directly adjacent to said grading interlayer and being lattice mismatched with respect to said middle second subcell, and having a fourth band gap smaller than said second band gap; a plurality of metal grid lines disposed on the top surface of the first solar subcell, including at least one metal contact pad electrically connected to said grid lines and disposed adjacent to a first peripheral edge of said first solar subcell; a metal contact layer adjacent to said third solar subcell for making an electrical contact to the third solar subcell; a metallic supporting film deposed adjacent to the metal contact layer, and a discrete metal interconnection member extending to the metal contact layer through the cut-out, the interconnection member having a first planar end-portion welded to the metal contact layer, a second portion connected to the first end-portion and extending through the cut-out and above the surface of the solar cell, and a third portion connected to the second portion and being serpentine in shape.

In some embodiments, an adhesive layer attaches the solar cells to the flexible film.

In some embodiments, the adhesive layer includes polyimide or epoxy.

In some embodiments, the bonding layer is a metallic solder alloy film comprised of molybdenum, Kovar, or other Fe—Ni alloys suitably CTE matched to the semiconductor.

In some embodiments, the metallic layer is a solid metallic foil having a thickness between 0.001 and 0.005 inches.

In some embodiments, the semiconductor solar cells have a thickness of less than 50 microns.

In another aspect, the present invention provides a solar cell array comprising a supporting substrate including a molybdenum, Kovar or Fe—Ni alloy suitably CTE matched to the semiconductor foil having a thickness between 0.001 and 0.005 inches, and an array of solar cells mounted on the supporting substrates.

Some implementations of the present invention may incorporate or implement fewer of the aspects and features noted in the foregoing summaries.

Additional aspects, advantages, and novel features of the present invention will become apparent to those skilled in the art from this disclosure, including the following detailed description as well as by practice of the invention. While the invention is described below with reference to preferred embodiments, it should be understood that the invention is not limited thereto. Those of ordinary skill in the art having access to the teachings herein will recognize additional applications, modifications and embodiments in other fields, which are within the scope of the invention as disclosed and claimed herein and with respect to which the invention could be of utility.

### BRIEF DESCRIPTION OF THE DRAWINGS

The invention will be better and more fully appreciated by reference to the following detailed description when considered in conjunction with the accompanying drawings, wherein:

FIG. 1 is a graph representing the bandgap of certain binary materials and their lattice constants;

FIG. 2 is a cross-sectional view of the solar cell of the invention after the deposition of semiconductor layers on the growth substrate;

FIG. 3 is a cross-sectional view of the solar cell of FIG. 2 after the next process step;

FIG. 4 is a cross-sectional view of the solar cell of FIG. 3 after the next process step;

FIG. 5A is a cross-sectional view of the solar cell of FIG. 4 after the next process step in which a surrogate substrate is attached;

FIG. 5B is a cross-sectional view of the solar cell of FIG. 5A after the next process step in which the original substrate is removed;

FIG. 5C is another cross-sectional view of the solar cell of FIG. 5B with the surrogate substrate on the bottom of the Figure;

FIG. 6 is a simplified cross-sectional view of the solar cell of FIG. 5C after the next process step;

FIG. 7 is a cross-sectional view of the solar cell of FIG. 6 after the next process step;

FIG. 8 is a cross-sectional view of the solar cell of FIG. 7 after the next process step;

FIG. 9 is a cross-sectional view of the solar cell of FIG. 8 after the next process step;

FIG. 10A is a top plan view of a wafer in which four solar cells are fabricated;

FIG. 10B is a bottom plan view of the wafer in which the four solar cells are fabricated;

FIG. 10C is a top plan view of a wafer in which two solar cells are fabricated;

FIG. 11 is a cross-sectional view of the solar cell of FIG. 9 after the next process step;

FIG. 12A is a cross-sectional view of the solar cell of FIG. 11 after the next process step, in a view orthogonal to the grid lines;

FIG. 12B is a cross-sectional view of the solar cell of FIG. 11 after the next process step, in a view along a grid line;

FIG. 13A is a top plan view of the wafer of FIG. 10A depicting the surface view of the trench etched around the cell, after the next process step;

FIG. 13B is a top plan view of the wafer of FIG. 10C depicting the surface view of the trench etched around the cell, after the next process step;

FIG. 13C is a top plan view of the wafer of FIG. 13B, after the next process steps;

FIG. 14A is a cross-sectional view of the solar cell of FIG. 13C though the 14A-14A plane;

FIG. 14B is a cross-sectional view of the solar cell of FIG. 14A following the removal of the surrogate substrate and attachment of an interconnect;

FIG. 14C is a cross-sectional view of the solar cell of FIG. 14B after the attachment of a cover glass;

FIG. 14D is a cross-sectional view of the solar cell of FIG. 14D after the next process step of alignment with an adjacent similar solar cell;

FIG. 14E is a cross-sectional view of the solar cell of FIG. 14E after the next process step of welding the interconnection member of the first solar cell to the metallic supporting film of the second solar cell;

FIG. 15 is a graph of the doping profile in the base and emitter layers of a subcell in the metamorphic solar cell according to the present invention;

FIG. 16 is a graph that depicts the current and voltage characteristics of an inverted metamorphic multijunction solar cell according to the present invention.

FIG. 17 is a graph representing the Al, Ga and In mole fractions versus the lattice constant in a AlGaInAs material system that is necessary to achieve a constant 1.5 eV band gap;

FIG. 18 is a diagram representing the relative concentration of Al, In, and Ga in an AlGaInAs material system needed to have a constant band gap with various designated values (ranging from 0.4 eV to 2.1 eV) as represented by curves on the diagram; and

FIG. 19 is a graph representing the Ga mole fraction to the Al to In mole fraction in a AlGaInAs material system that is necessary to achieve a constant 1.51 eV band gap.

### DESCRIPTION OF THE PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

The basic concept of fabricating an inverted metamorphic multijunction (IMM) solar cell is to grow the subcells of the solar cell on a substrate in a “reverse” sequence. That is, the high band gap subcells (i.e. subcells with band gaps in the range of 1.8 to 2.1 eV), which would normally be the “top” subcells facing the solar radiation, are initially grown epitaxially directly on a semiconductor growth substrate, such as for example GaAs or Ge, and such subcells are consequently lattice-matched to such substrate. One or more lower band gap middle subcells (i.e. with band gaps in the range of 1.2 to 1.8 eV) can then be grown on the high band gap subcells.

At least one lower subcell is formed over the middle subcell such that the at least one lower subcell is substantially lattice-mismatched with respect to the growth substrate and such that the at least one lower subcell has a third lower band gap (i.e., a band gap in the range of 0.7 to 1.2 eV). A surrogate substrate or support structure is then attached or provided over the “bottom” or substantially lattice-mismatched lower subcell, and the growth semiconductor substrate is subsequently removed. (The growth substrate may then subsequently be re-used for the growth of second and subsequent solar cells).

A variety of different features and aspects of inverted metamorphic multijunction solar cells are disclosed in the related applications noted above. Some or all of such features may be included in the structures and processes associated with the solar cells of the present invention. Neither, some or all of such aspects may be included in the structures and processes associated with the semiconductor devices and/or solar cells of the present invention.

The present disclosure provides a process for permanently mounting an inverted metamorphic solar cell on a flexible support, and providing an electrical interconnect member for connecting the cell to adjacent cells in a bifacial manner. More specifically, the present disclosure intends to provide a relatively simple and reproducible technique that is suitable for use in a high volume production environment in which various semiconductor layers are deposited in an MOCVD reactor, and subsequent processing steps are defined and selected to minimize any physical damage to the quality of the deposited layers, thereby ensuring a relatively high yield of operable solar cells meeting specifications at the conclusion of the fabrication processes.

Prior to discussing the specific embodiments of the present disclosure, a brief discussion of inverted metamorphic solar cells and the context of the composition or deposition of various specific layers in embodiments of the product as specified and defined by Applicant is in order.

There are a multitude of properties that should be considered in specifying and selecting the composition of, inter alia, a specific semiconductor layer, the back metal layer, the adhesive or bonding material, or the composition of the supporting material for mounting a solar cell thereon. For example, some of the properties that should be considered when selecting a particular layer or material are electrical properties (e.g. conductivity), optical properties (e.g., band gap, absorbance and reflectance), structural properties (e.g., thickness, strength, flexibility, Young's modulus, etc.), chemical properties (e.g., growth rates, the “sticking coefficient” or ability of one layer to adhere to another, stability of dopants and constituent materials with respect to adjacent layers and subsequent processes, etc.), thermal properties (e.g., thermal stability under temperature changes, coefficient of thermal expansion), and manufacturability (e.g., availability of materials, process complexity, process variability and tolerances, reproducibility of results over high volume, reliability and quality control issues).

In view of the trade-offs among these properties, it is not always evident that the selection of a material based on one of its characteristic properties is always or typically “the best” or “optimum” from a commercial standpoint or for Applicant's purposes. For example, theoretical studies may suggest the use of a quaternary material with a certain band gap for a particular subcell would be the optimum choice for that subcell layer based on fundamental semiconductor physics. As an example, the teachings of academic papers and related proposals for the design of very high efficiency (over 40%) solar cells may therefore suggest that a solar cell designer specify the use of a quaternary material (e.g., InGaAsP) for the active layer of a subcell. A few such devices may actually be fabricated by other researchers, efficiency measurements made, and the results published as an example of the ability of such researchers to advance the progress of science by increasing the demonstrated efficiency of a compound semiconductor multijunction solar cell. Although such experiments and publications are of “academic” interest, from the practical perspective of the Applicants in designing a compound semiconductor multijunction solar cell to be produced in high volume at reasonable cost and subject to manufacturing tolerances and variability inherent in the production processes, such an “optimum” design from an academic perspective is not necessarily the most desirable design in practice, and the teachings of such studies more likely than not point in the wrong direction and lead away from the proper design direction. Stated another way, such references may actually “teach away” from Applicant's research efforts and the ultimate solar cell design proposed by the Applicants.

To take an example in just one layer, specifically the composition of the back metal layer in the solar cell according to the present disclosure and in the related applications of Applicant, some may argue that the prior art suggests the desirability of a “highly reflective” electrode for use as a back contact in an optoelectronic semiconductor device. One of ordinary skill in the art may than focus on the reflectivity properties of various metals, and conclude that from standard tables of reflectivity of metals that the choice of silver (Ag) would be a suitable choice for the back contact in the disclosed solar cell in order to maximize reflectivity and improve efficiency. On the other hand, an inverted metamorphic solar cell does not have the same or even similar structure as an optoelectronic semiconductor device, and the fabrication and process steps associated with producing an inverted structure present a number of challenges not encountered in the fabrication of other compound semiconductor devices on permanent and rigid substrates.

The problem presented by the choice of silver as a back metal is paradigmatic of the choice of any specific material based on certain preconceived notions of the critical parameters at issue in selecting a material constituent of any layer. There may be a finite number of metal elements in the periodic table, or column III or column V semiconductor materials, but there are not a small, finite number of identifiable predictable solutions to the potential problems arising in a complex manufacturing process for fabricating inverted metamorphic solar cells. In view of the foregoing example, it is further evident that the identification of one particular constituent element (e.g. indium, or aluminum) in a particular subcell, or the thickness, band gap, doping, or other characteristic of the incorporation of that material in a particular subcell, is not a “result effective variable” that one skilled in the art can simply specify and incrementally adjust to a level and thereby increase the efficiency of a solar cell. The efficiency of a solar cell is not a simple linear algebraic equation as a function of the amount of gallium or aluminum or other element in a particular layer. The growth of each of the epitaxial layers of a solar cell in an MOCVD reactor is a non-equilibrium thermodynamic process with dynamically changing spatial and temporal boundary conditions that is not readily or predictably modeled. The formulation and solution of the relevant simultaneous partial differential equations covering such processes are not within the ambit of those of ordinary skill in the art in the field of solar cell design.

Even when it is known that particular variables have an impact on electrical, optical, chemical, thermal or other characteristics, the nature of the impact often cannot be predicted with much accuracy, particularly when the variables interact in complex ways, leading to unexpected results and unintended consequences. Thus, significant trial and error, which may include the fabrication of many test devices, often is required to determine whether a proposed structure with layers of particular compositions, actually will operate as intended, let alone whether it can be fabricated in a reproducible high volume manner within the manufacturing tolerances and variability inherent in the production process, and necessary for the design of a commercially viable device.

As in the case here, where multiple variables interact in unpredictable ways, the proper choice of the combination of variables can produce new and unexpected results, and constitute an “inventive step”.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

It should be apparent to one skilled in the art, that the inclusion of additional semiconductor layers within the cell with similar or additional functions and properties is also within the scope of the present invention.

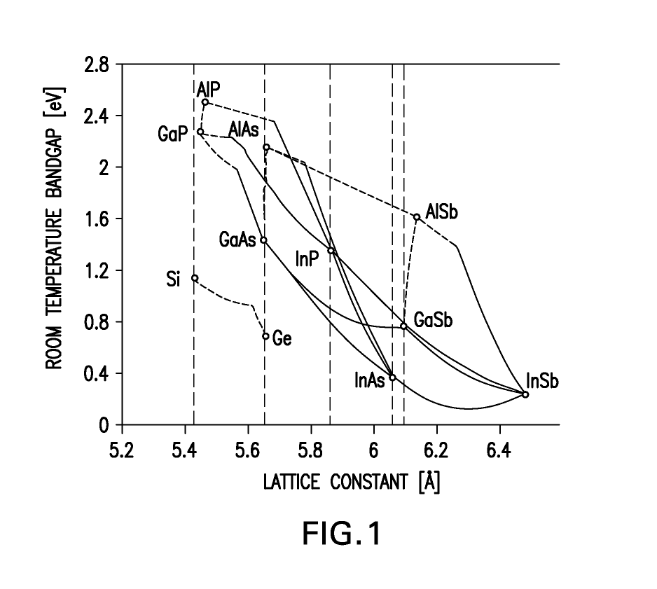

FIG. 1 is a graph representing the band gap of certain binary materials and their lattice constants. The band gap and lattice constants of ternary materials are located on the lines drawn between typical associated binary materials (such as the ternary material GaAlAs being located between the GaAs and AlAs points on the graph, with the band gap of the ternary material lying between 1.42 eV for GaAs and 2.16 eV for AlAs depending upon the relative amount of the individual constituents). Thus, depending upon the desired band gap, the material constituents of ternary materials can be appropriately selected for growth.

The lattice constants and electrical properties of the layers in the semiconductor structure are preferably controlled by specification of appropriate reactor growth temperatures and times, and by use of appropriate chemical composition and dopants. The use of a vapor deposition method, such as Organo Metallic Vapor Phase Epitaxy (OMVPE), Metal Organic Chemical Vapor Deposition (MOCVD), or other vapor deposition methods for the reverse growth may enable the layers in the monolithic semiconductor structure forming the cell to be grown with the required thickness, elemental composition, dopant concentration and grading and conductivity type.

The present disclosure is directed to a growth process using a metal organic chemical vapor deposition (MOCVD) process in a standard, commercially available reactor suitable for high volume production. More particularly, the present disclosure is directed to the materials and fabrication steps that are particularly suitable for producing commercially viable inverted metamorphic multijunction solar cells using commercially available equipment and established high-volume fabrication processes, as contrasted with merely academic expositions of laboratory or experimental results. The thickness of the epitaxial layers forming the inverted metamorphic multijunction solar cells disclosed in the present and related applications noted above are 12 microns or more. The thickness of the graded metamorphic buffer layer may be from 2.5 to 3.0 microns. The time required to grow such epitaxial layers is a significant factor which distinguishes a high volume commercial MOCVD process from processes using MBE growth, for example. Currently available MBE systems require about one hour to grow one micron of epitaxial material. Thus, the growth of a graded metamorphic buffer layer may take as long as three hours. By contrast, the growth of the same structure using an MOCVD process can take less than 45 minutes.

It should be noted that the layers of with a certain target composition in a semiconductor structure grown in an MOCVD process are inherently physically different than the layers of an identical target composition grown by another process, e.g. Molecular Beam Epitaxy (MBE). The material quality (i.e., morphology, stoichiometry, number and location of lattice traps, impurities, and other lattice defects) of an epitaxial layer in a semiconductor structure is different depending upon the process used to grow the layer, as well as the process parameters associated with the growth. MOCVD is inherently a chemical reaction process, while MBE is a physical deposition process. The chemicals used in the MOCVD process are present in the MOCVD reactor and interact with the wafers in the reactor, and affect the composition, doping, and other physical, optical and electrical characteristics of the material. For example, the precursor gases used in an MOCVD reactor are incorporated into the resulting processed wafer material, and have certain identifiable electro-optical consequences which are more advantageous in certain specific applications of the semiconductor structure, such as in photoelectric conversion in structures designed as solar cells. Such high order effects of processing technology do result in relatively minute but actually observable differences in the material quality grown or deposited according to one process technique compared to another. Thus, devices fabricated at least in part using an MOCVD reactor or using a MOCVD process have inherent different physical material characteristics, which may have an advantageous effect over the identical target material deposited using alternative processes.

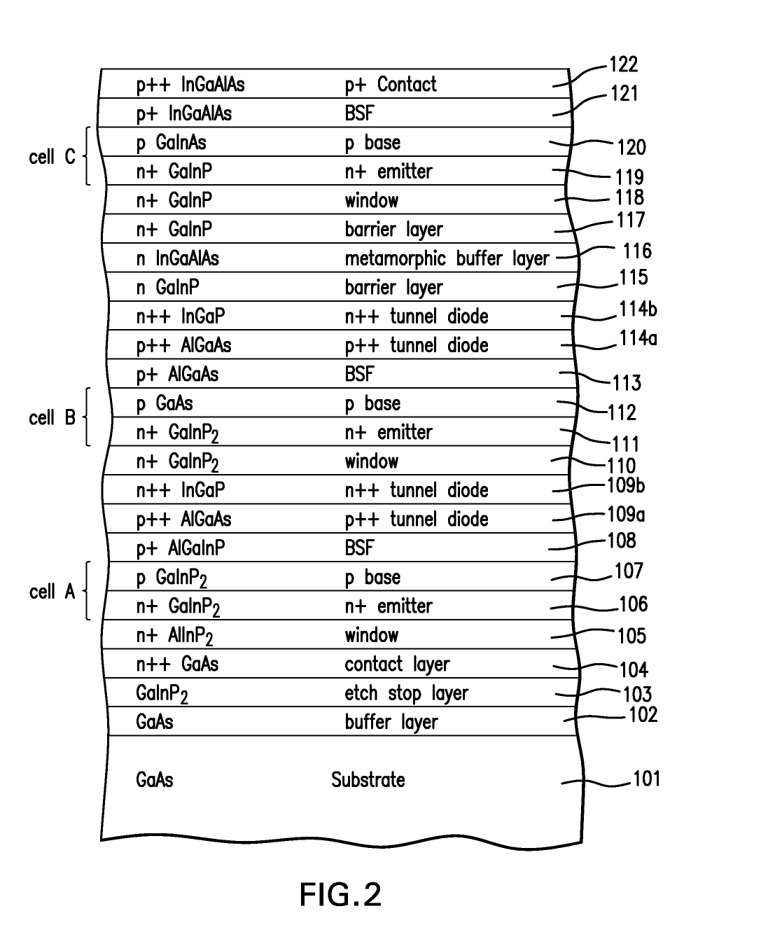

FIG. 2 depicts the multijunction solar cell according to the present invention after the sequential formation of the three subcells A, B and C on a GaAs growth substrate. More particularly, there is shown a substrate 101, which is preferably gallium arsenide (GaAs), but may also be germanium (Ge) or other suitable material. For GaAs, the substrate is preferably a 15° off-cut substrate, that is to say, its surface is orientated 15° off the (100) plane towards the (111) A plane, as more fully described in U.S. patent application Ser. No. 12/047,944, filed Mar. 13, 2008. Other alternative growth substrates, such as described in U.S. patent application Ser. No. 12/337,014 filed Dec. 17, 2008, may be used as well.

In the case of a Ge substrate, a nucleation layer (not shown) is deposited directly on the substrate 101. On the substrate, or over the nucleation layer (in the case of a Ge substrate), a buffer layer 102 and an etch stop layer 103 are further deposited. In the case of GaAs substrate, the buffer layer 102 is preferably GaAs. In the case of Ge substrate, the buffer layer 102 is preferably InGaAs. A contact layer 104 of GaAs is then deposited on layer 103, and a window layer 105 of AlInP is deposited on the contact layer. The subcell A, consisting of an n+ emitter layer 106 and a p-type base layer 107, is then epitaxially deposited on the window layer 105. The subcell A is generally latticed matched to the growth substrate 101.

It should be noted that the multijunction solar cell structure could be formed by any suitable combination of group III to V elements listed in the periodic table subject to lattice constant and bandgap requirements, wherein the group III includes boron (B), aluminum (Al), gallium (Ga), indium (In), and thallium (T). The group IV includes carbon (C), silicon (Si), germanium (Ge), and tin (Sn). The group V includes nitrogen (N), phosphorus (P), arsenic (As), antimony (Sb), and bismuth (Bi).

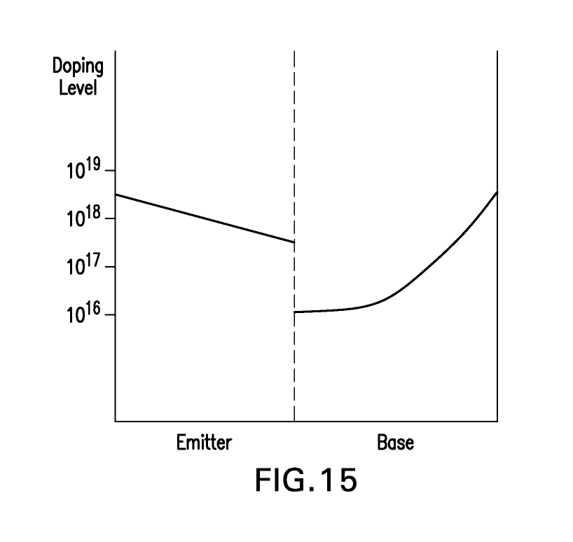

In the preferred embodiment, the emitter layer 106 is composed of InGa(Al)P and the base layer 107 is composed of InGa(Al)P. The aluminum or Al term in parenthesis in the preceding formula means that Al is an optional constituent, and in this instance may be used in an amount ranging from 0% to 30%. The doping profile of the emitter and base layers 106 and 107 according to the present invention will be discussed in conjunction with FIG. 15.

Subcell A will ultimately become the “top” subcell of the inverted metamorphic structure after completion of the process steps according to the present invention to be described hereinafter.

On top of the base layer 107 a back surface field (“BSF”) layer 108 preferably p+AlGaInP is deposited and used to reduce recombination loss.

The BSF layer 108 drives minority carriers from the region near the base/BSF interface surface to minimize the effect of recombination loss. In other words, a BSF layer 18 reduces recombination loss at the backside of the solar subcell A and thereby reduces the recombination in the base.

On top of the BSF layer 108 is deposited a sequence of heavily doped p-type and n-type layers 109a and 109b that forms a tunnel diode, i.e. an ohmic circuit element that connects subcell A to subcell B. Layer 109a is preferably composed of p++ AlGaAs, and layer 109b is preferably composed of n++ InGaP.

On top of the tunnel diode layers 109 a window layer 110 is deposited, preferably n+ InGaP. The advantage of utilizing InGaP as the material constituent of the window layer 110 is that it has an index of refraction that closely matches the adjacent emitter layer 111, as more fully described in U.S. patent application Ser. No. 12/258,190, filed Oct. 24, 2008. More generally, the window layer 110 used in the subcell B operates to reduce the interface recombination loss. It should be apparent to one skilled in the art, that additional layer(s) may be added or deleted in the cell structure without departing from the scope of the present invention.

On top of the window layer 110 the layers of subcell B are deposited: the n-type emitter layer 111 and the p-type base layer 112. These layers are preferably composed of InGaP and In_{0.015}GaAs respectively (for a Ge substrate or growth template), or InGaP and GaAs respectively (for a GaAs substrate), although any other suitable materials consistent with lattice constant and bandgap requirements may be used as well. Thus, subcell B may be composed of a GaAs, GaInP, GaInAs, GaAsSb, or GaInAsN emitter region and a GaAs, GaInAs, GaAsSb, or GaInAsN base region. The doping profile of layers 111 and 112 according to some embodiments of the present invention will be discussed in conjunction with FIG. 15.

In previously disclosed implementations of an inverted metamorphic solar cell, the middle cell was a homostructure. In some embodiments of the present invention, similarly to the structure disclosed in U.S. patent application Ser. No. 12/023,772, the middle subcell becomes a heterostructure with an InGaP emitter and its window is converted from InAlP to InGaP. This modification eliminated the refractive index discontinuity at the window/emitter interface of the middle sub-cell. Moreover, the window layer 110 is preferably doped three times that of the emitter 111 to move the Fermi level up closer to the conduction band and therefore create band bending at the window/emitter interface which results in constraining the minority carriers to the emitter layer.

In one of the embodiments of the present invention, the middle subcell emitter has a band gap equal to the top subcell emitter, and the bottom subcell emitter has a band gap greater than the band gap of the base of the middle subcell. Therefore, after fabrication of the solar cell, and implementation and operation, neither the emitters of middle subcell B nor the bottom subcell C will be exposed to absorbable radiation. Substantially all of the photons representing absorbable radiation will be absorbed in the bases of cells B and C, which have narrower band gaps than the respective emitters. In summary, the advantages of the embodiments using heterojunction subcells are: (i) the short wavelength response for both subcells are improved, and (ii) the bulk of the radiation is more effectively absorbed and collected in the narrower band gap base. The overall effect will be to increase the short circuit current J_{sc}.

On top of the cell B is deposited a BSF layer 113 which performs the same function as the BSF layer 109. The p++/n++ tunnel diode layers 114a and 114b respectively are deposited over the BSF layer 113, similar to the layers 109a and 109b, forming an ohmic circuit element to connect subcell B to subcell C. The layer 114a is preferably composed of p++ AlGaAs, and layer 114b is preferably composed of n++ InGaP.

In some embodiments, barrier layer 115, preferably composed of n-type InGa(Al)P, is deposited over the tunnel diode 114a/114b, to a thickness of about 1.0 micron. Such barrier layer is intended to prevent threading dislocations from propagating, either opposite to the direction of growth into the middle and top subcells A and B, or in the direction of growth into the bottom subcell C, and is more particularly described in copending U.S. patent application Ser. No. 11/860,183, filed Sep. 24, 2007.

A metamorphic layer (or graded interlayer) 116 is deposited over the barrier layer 115 using a surfactant. Layer 116 is referred to as a graded interlayer since in some embodiments it is preferably a compositionally step-graded series of InGaAlAs layers, preferably with monotonically changing lattice constant in each step, so as to achieve a gradual transition in lattice constant in the semiconductor structure from the lattice constant of subcell B to the lattice constant of subcell C while minimizing threading dislocations from occurring. In some embodiments, the band gap of layer 116 is constant throughout its thickness, preferably approximately equal to 1.5 eV, or otherwise consistent with a value slightly greater than the base bandgap of the middle subcell B. In some embodiments, the graded interlayer may be composed of (InₓGa₁₋ₓ)_{y} Al_{1-y}As, with 0<x<1, 0<y<1, and the values of x and y selected for each respective layer such that the band gap of the entire interlayer remains constant at approximately 1.50 eV or other appropriate band gap over its thickness.

In an alternative embodiment where the solar cell has only two subcells, and the “middle” cell B is the uppermost or top subcell in the final solar cell, wherein the “top” subcell B would typically have a bandgap of 1.8 to 1.9 eV, then the band gap of the graded interlayer would remain constant at 1.9 eV.

In the inverted metamorphic structure described in the Wanlass et al. paper cited above, the metamorphic layer consists of nine compositionally graded InGaP steps, with each step layer having a thickness of 0.25 micron. As a result, each layer of Wanlass et al. has a different bandgap. In one of the preferred embodiments of the present invention, the layer 116 is composed of a plurality of layers of InGaAlAs, with monotonically changing lattice constant, each layer having the same bandgap, approximately 1.5 eV.

The advantage of utilizing a constant bandgap material such as InGaAlAs over a phosphide based material is that arsenide-based semiconductor material is much easier to process in standard commercial MOCVD reactors, compared to phosphide materials, while the small amount of aluminum provides a bandgap that assures radiation transparency of the metamorphic layers.

Although one of the preferred embodiments of the present invention utilizes a plurality of layers of InGaAlAs for the metamorphic layer 116 for reasons of manufacturability and radiation transparency, other embodiments of the present invention may utilize different material systems to achieve a change in lattice constant from subcell B to subcell C. Thus, the system of Wanlass using compositionally graded InGaP is a second embodiment of the present invention. Other embodiments of the present invention may utilize continuously graded, as opposed to step graded, materials. More generally, the graded interlayer may be composed of any of the As, P, N, Sb based III-V compound semiconductors subject to the constraints of having the in-plane lattice parameter greater or equal to that of the second solar cell and less than or equal to that of the third solar cell, and having a bandgap energy greater than that of the second solar cell.

Since the present disclosure (and the related applications noted above) are directed to high volume manufacturing processes using metalorganic vapor phase epitaxy (MOVPE) reactors to form the solar cell epitaxial layers, a short discussion of some of the considerations associated with such processes and methods associated with the formation of the graded interlayer(s) are in order here.

First, it should be noted that the advantage of utilizing an interlayer material such as AlGaInAs is that arsenide-based semiconductor material is much easier to process from a manufacturing standpoint using present state-of-the-art high volume manufacturing metalorganic vapor phase epitaxy (MOVPE) reactors than either the AlGaInAsP, or GaInP compounds, or in general any material including phosphorus. Simply stated, the use of a III-V arsenide compound is much more desirable than a III-V phosphide compound from the perspectives of cost, ease of growth, reactor maintenance, waste handling and personal safety.

The cost advantage of the use of the AlGaInAs quaternary grading material relative to a GaInP ternary grading material, as an example, is a consequence of several factors. First, the use of a GaInP grading approach requires indium mole fractions of the order of 60% (i.e., the required material is Ga_{0.4}In_{0.6}P) whereas the use of the AlGaInAs quaternary requires only 15% indium (i.e., the required material is Al_{y}(Ga_{0.85}In_{0.15})_{1-y}As). In addition to the difference in the material itself, there is a further difference in the amount of precursor gases (trimethylgallium, trimethylindium, and arsine) that must be input to the reactor in order to achieve the desired composition. In particular, the ratio of the amount of precursor gases into the reactor to provide Group V elements, to the amount of precursor gases to provide Group III elements (such ratio being referred to as the “input V/III ratio”) is typically five to ten times greater to produce a phosphide compound compared to producing an arsenide compound. As a illustrative quantification of the cost of producing a phosphide compound in a commercial operational MOPVE reactor process compared to the cost of producing an arsenide compound, Table 1 below presents the typical pro-form a costs of each element of the AlGaInAs and GaInP compounds for producing a graded interlayer of the type described in the present disclosure expressed on a per mole basis. Of course, like many commodities, the price of chemical compounds fluctuate from time to time and vary in different geographic locations and countries and from supplier to supplier. The prices used in Table 1 are representative for purchases in commercial quantities in the United States at the time of the present disclosure. The cost calculations make the assumption (typical for epitaxial processes using current commercial MOVPE reactors) that the input V/III ratios are 20 and 120 for the arsenide and phosphide compounds respectively. Such a choice of value of the ratio is merely illustrative for a typical process, and some processes may use even higher ratios for producing a graded interlayer of the type described in the present disclosure. The practical consequence of the inlet V/III ratio is that one will use 20 moles of As to one (1) mole of AlGaIn in the formation of the Applicant's quaternary material AlGaInAs, or 120 moles of P to 1 mole of GaIn in the formation of the interlayer using the ternary material GaInP. These assumptions along with the molar cost of each of the constituent elements indicate that the cost of fabrication of the AlGaInAs based grading interlayer will be approximately 25% of the cost of fabrication of a similar phosphide based grading interlayer. Thus, there is an important economic incentive from a commercial and manufacturing perspective to utilize an arsenide compound as opposed to a phosphide compound for the grading interlayer.

TABLE 1
Cost estimate of one mole of each of the AlGaInAs and GaInP grading layers

| | | | | | Cost | | Cost |
|---|---|---|---|---|---|---|---|
| | | | | | Molecular | | Molecular |
| Ele- | MW | | Cost/mole | MF | Mole of | MF | Mole of |
| ment | (gms) | $/gm | ($) | AlGaIn | Al.17Ga.68In.15 | GaInP | Ga.4In.6 |
| Al | 27 | 10.2 | 275.4 | 0.17 | 46.818 | 0 | 0 |
| Ga | 70 | 2.68 | 187.6 | 0.68 | 127.568 | 0.4 | 75.04 |
| In | 115 | 28.05 | 3225.75 | 0.15 | 483.8625 | 0.6 | 1935.45 |
| | | | | Approx OM | 658.2485 | | 2010.49 |
| | | | | Cost/mole = | | | |
| | Cost/ | V/III | | | Cost/mole of | | Cost/mole of |
| | mole ($) | ratio | | | Arsenic | | phosphorus |
| AsH3 | $7.56 | 20 | $151.20 | | $151.20 | | |
| PH3 | $9.49 | 120 | $1,138.80 | | | | $1,138.54 |
| | | | | Approx cost/ | $809.45 | | $3,149.03 |
| | | | | molecular | | | |
| | | | | mole = | | | |

The “ease of growth” of an arsenide compound as opposed to a phosphide compound for the grading interlayer in a high volume manufacturing environment is another important consideration and is closely related to issues of reactor maintenance, waste handling and personal safety. More particularly, in a high volume manufacturing environment the abatement differences between arsenide and phosphide based processes affect both cost and safety. The abatement of phosphorus is more time consuming, and hazardous than that required for arsenic. Each of these compounds builds up over time in the downstream gas flow portions of the MOVPE growth reactor. As such, periodic reactor maintenance for removal of these deposited materials is necessary to prevent adverse affects on the reactor flow dynamics, and thus the repeatability and uniformity of the epitaxial structures grown in the reactor. The difference in handling of these waste materials is significant. Arsenic as a compound is stable in air, non-flammable, and only represents a mild irritant upon skin contact. Phosphorus however, must be handled with considerably more care. Phosphorus is very flammable and produces toxic fumes upon burning and it is only moderately stable in air. Essentially the differences are manifest by the need for special handling and containment materials and procedures when handling phosphorus to prevent either combustion or toxic exposure to this material whereas using common personal protection equipment such as gloves, and a particle respirator easily accommodates the handling of arsenic.

Another consideration related to “ease of growth” that should be noted in connection with the advantages of a AlGaInAs based grading interlayer process compared to a AlGaInAsP compound derives from a frequently encountered issue when using an AlGaInAsP compound: the miscibility gap. A miscibility gap will occur if the enthalpy of mixing exceeds the entropy of mixing of two binary compounds AC and BC, where A, B and C are different elements. It is an established fact that the enthalpies of mixing of all ternary crystalline alloys of the form AₓB₁₋ₓC, based upon the binary semiconductor forms AC and BC are positive leading to miscibility gaps in these compounds. See, for example, the discussion in reference [1] noted below. In this example, the letters A and B designate group III elements and letter C designates a group V element. As such, mixing of the binary compounds is said to occur on the group III sublattice. However, because OMVPE growth takes place under non-equilibrium conditions, the miscibility gap is not really a practical problem for accessing the entire ternary III-V semiconductor phase space. For the case of quaternary compounds of the form AₓB₁₋ₓC_{y}D_{1-y} where mixing of the binary alloys, AC, AD, BC, and BD occurs on both the group III and group V sublattices, the immiscibility problem is accentuated. Specifically for the GaP, InP, GaAs, InAs system, the region of immiscibility is quite large at growth temperatures appropriate for the OMVPE technique. See, for example, the discussion in reference [2] noted below. The resulting miscibility gap will prevent one from producing the requisite AlGaInAsP compounds needed for optical transparent grading of the IMM solar cell.

### REFERENCES

V. A. Elyukhin, E. L. Portnoi, E. A. Avrutin, and J. H. Marsh, J. Crystal Growth 173 (1997) pp 69-72.
G. B. Stringfellow, Organometallic Vapor-Phase Epitaxy (Academic Press, New York 1989).

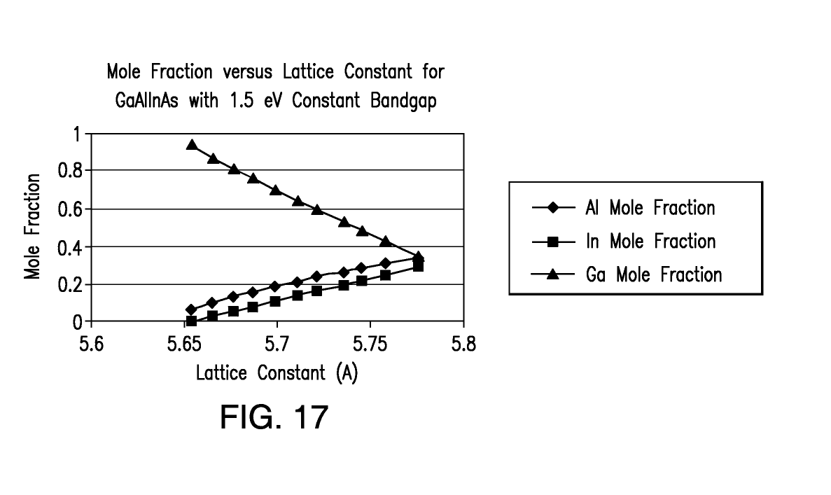

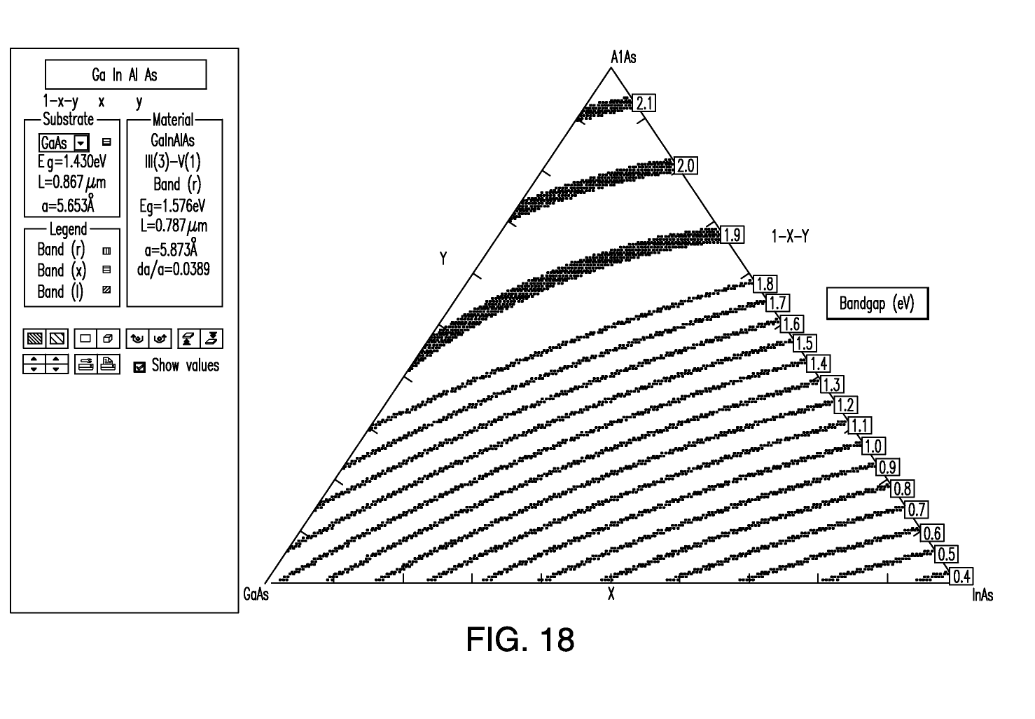

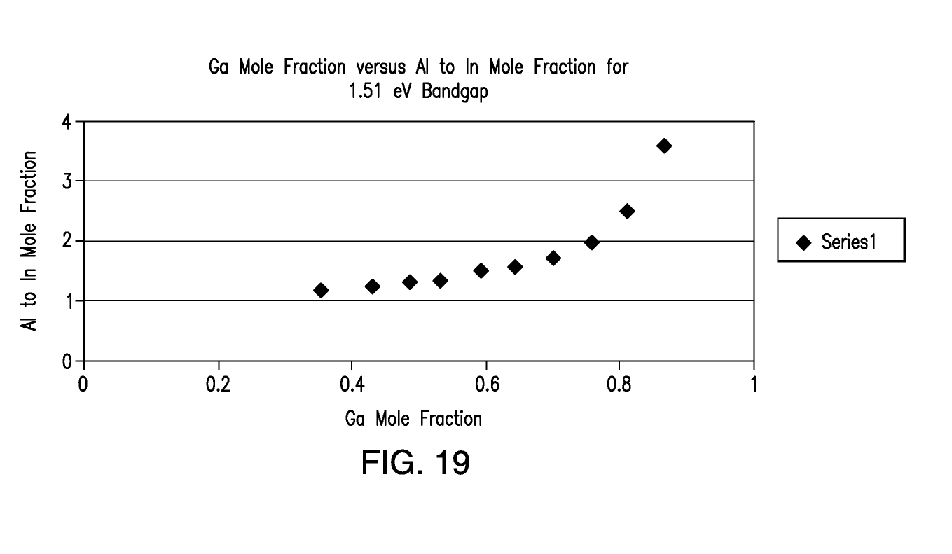

The fabrication of a step graded (or continuous graded) interlayer in an MOCVD process can be more explicitly described in a sequence of conceptual and operational steps which we describe here for pedagogical clarity. First, the appropriate band gap for the interlayer must be selected. In one of the disclosed embodiments, the desired constant band gap is 1.5 eV. Second, the most appropriate material system (i.e., the specific semiconductor elements to form a compound semiconductor alloy) must be identified. In the disclosed embodiment, these elements are Al, Ga, In, and As. Third, a computation must be made, for example using a computer program, to identify the class of compounds of Al_{y}(GaₓIn₁₋ₓ)_{1-y}As for specific x and y that have a band gap of 1.5 eV. An example of such a computer program output that provides a very rough indication of these compounds is illustrated in FIGS. 18 and 19. Fourth, based upon the lattice constants of the epitaxial layers adjoining the graded interlayer, a specification of the required lattice constants for the top surface of the interlayer (to match the adjacent semiconductor layer), and the bottom surface of the interlayer (to match the adjacent semiconductor layer) must be made. Fifth, based on the required lattice constants, the compounds of Al_{y}(GaₓIn₁₋ₓ)_{1-y}As for specific x and y that have a band gap of 1.5 eV may be identified. Again, a computation must be made, and as an example, the data may be displayed in a graph such as FIG. 18 representing the Al, Ga and In mole fractions in a AlGaInAs material system that is necessary to achieve a constant 1.5 eV band gap. Assuming there is a small number (e.g. typically in the range of seven, eight, nine, ten, etc.) of steps or grades between the top surface and the bottom surface, and that the lattice constant difference between each step is made equal, the bold markings in FIG. 17 represent selected lattice constants for each successive sublayer in the interlayer, and the corresponding mole fraction of Al, Ga and In needed to achieve that lattice constant in that respective sublayer may be readily obtained by reference to the axes of the graph. Thus, based on an analysis of the data in FIGS. 18 and 19, the reactor may be programmed to introduce the appropriate quantities of precursor gases (as determined by flow rates at certain timed intervals) into the reactor so as to achieve a desired specific Al_{y}(GaₓIn₁₋ₓ)_{1-y}As composition in that sublayer so that each successive sublayer maintains the constant band gap of 1.5 eV and a monotonically increasing lattice constant. The execution of this sequence of steps, with calculated and determinate precursor gas composition, flow rate, temperature, and reactor time to achieve the growth of a Al_{y}(GaₓIn₁₋ₓ)_{1-y}As composition of the interlayer with the desired properties (lattice constant change over thickness, constant band gap over the entire thickness), in a repeatable, manufacturable process, is not to be minimalized or trivialized.

Although one embodiment of the present disclosure utilizes a plurality of layers of AlGaInAs for the metamorphic layer 116 for reasons of manufacturability and radiation transparency, other embodiments of the present disclosure may utilize different material systems to achieve a change in lattice constant from subcell B to subcell C. Other embodiments of the present disclosure may utilize continuously graded, as opposed to step graded, materials. More generally, the graded interlayer may be composed of any of the As, N, Sb based III-V compound semiconductors subject to the constraints of having the in-plane lattice parameter greater or equal to that of the second solar subcell and less than or equal to that of the third solar subcell, and having a band gap energy greater than that of the third solar cell.

In another embodiment of the present invention, an optional second barrier layer 117 may be deposited over the InGaAlAs metamorphic layer 116. The second barrier layer 117 will typically have a different composition than that of barrier layer 115, and performs essentially the same function of preventing threading dislocations from propagating. In the preferred embodiment, barrier layer 117 is n+ type GaInP.

A window layer 118 preferably composed of n+ type GaInP is then deposited over the barrier layer 117 (or directly over layer 116, in the absence of a second barrier layer). This window layer operates to reduce the recombination loss in subcell “C”. It should be apparent to one skilled in the art that additional layers may be added or deleted in the cell structure without departing from the scope of the present invention.

On top of the window layer 118, the layers of subcell C are deposited: the n+ emitter layer 119, and the p-type base layer 120. These layers are preferably composed of n+ type InGaAs and p type InGaAs respectively, or n+ type InGaP and p type InGaAs for a heterojunction subcell, although another suitable materials consistent with lattice constant and bandgap requirements may be used as well. The doping profile of layers 119 and 120 will be discussed in connection with FIG. 15.

A BSF layer 121, preferably composed of InGaAlAs, is then deposited on top of the cell C, the BSF layer performing the same function as the BSF layers 108 and 113.

Finally a high band gap contact layer 122, preferably composed of InGaAlAs, is deposited on the BSF layer 121.

This contact layer added to the bottom (non-illuminated) side of a lower band gap photovoltaic cell, in a single or a multijunction photovoltaic cell, can be formulated to reduce absorption of the light that passes through the cell, so that (1) an ohmic metal contact layer below (non-illuminated side) it will also act as a mirror layer, and (2) the contact layer doesn't have to be selectively etched off, to prevent absorption.

It should be apparent to one skilled in the art, that additional layer(s) may be added or deleted in the cell structure without departing from the scope of the present invention.

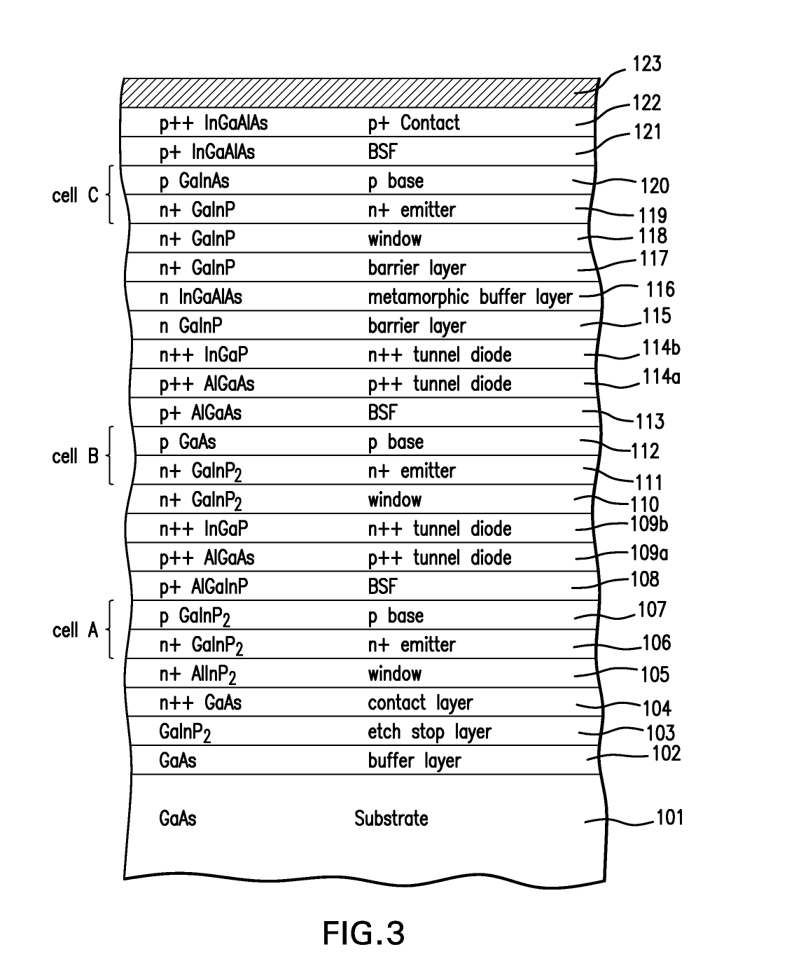

FIG. 3 is a cross-sectional view of the solar cell of FIG. 2 after the next process step in which a metal contact layer 123 is deposited over the p+ semiconductor contact layer 122. During subsequent processing steps, the semiconductor body and its associated metal layers and bonded structures will go through various heating and cooling processes, which may put stress on the surface of the semiconductor body. Accordingly, it is desirable to closely match the coefficient of thermal expansion of the associated layers or structures to that of the semiconductor body, while still maintaining appropriate electrical conductivity and structural properties of the layers or structures. Thus, in some embodiments, the metal contact layer 123 is selected to have a coefficient of thermal expansion (CTE) substantially similar to that of the adjacent semiconductor material. In relative terms, the CTE may be within a range of 0 to 15 ppm per degree Kelvin different from that of the adjacent semiconductor material. In the case of the specific semiconductor materials described above, in absolute terms, a suitable coefficient of thermal expansion of layer 123 would range from 5 to 7 ppm per degree Kelvin. A variety of metallic compositions and multilayer structures including the element molybdenum would satisfy such criteria. In some embodiments, the layer 123 would preferably include the sequence of metal layers Ti/Au/Mo/Ag/Au, Ti/Au/Mo/Ag, or Ti/Mo/Ag, where the thickness ratios of each layer in the sequence are adjusted to minimize the CTE mismatch to GaAs. Other suitable sequences and material compositions may be used in lieu of those disclosed above.

More generally, in other embodiments, the metal electrode layer may be selected to have a coefficient of thermal expansion that has a value less than 15 ppm per degree Kelvin.

In some embodiments, the metal electrode layer may have a coefficient of thermal expansion that has a value within 50% of the coefficient of thermal expansion of the adjacent semiconductor material.

In some embodiments, the metal electrode layer may have a coefficient of thermal expansion that has a value within 10% of the coefficient of thermal expansion of the adjacent semiconductor material.

In some embodiments, the metal contact scheme chosen is one that has a planar interface with the semiconductor, after heat treatment to activate the ohmic contact. This is done so that (i) a dielectric layer separating the metal from the semiconductor doesn't have to be deposited and selectively etched in the metal contact areas; and (ii) the contact layer is specularly reflective over the wavelength range of interest.

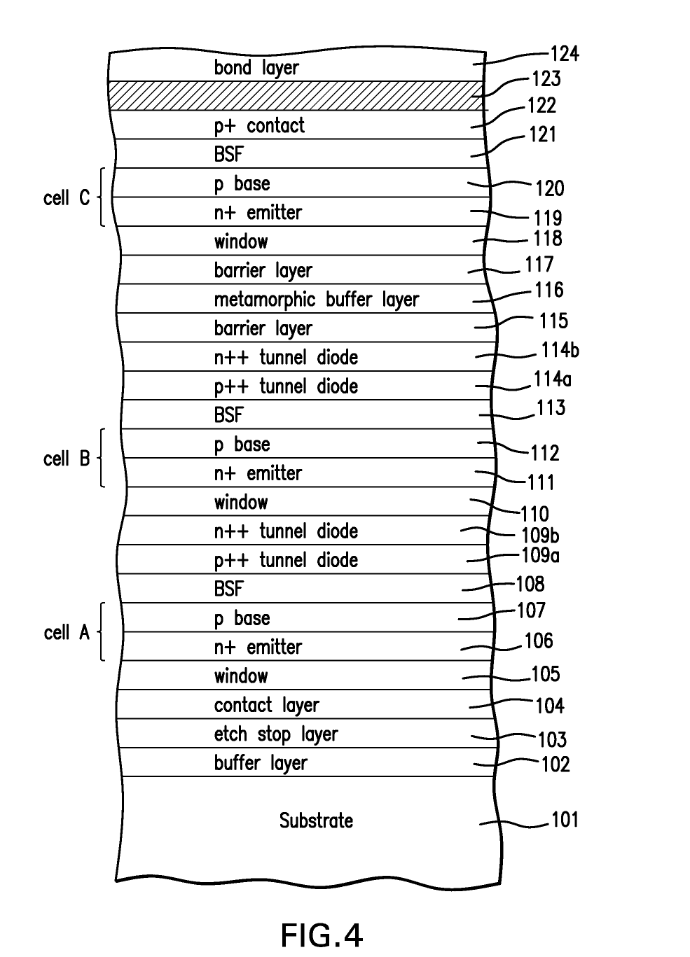

FIG. 4 is a cross-sectional view of the solar cell of FIG. 3 after the next process step in an embodiment in which a bonding layer 124 is deposited over the surface of a metallic film 125, and the bonding layer 124 then placed adjacent to the metal layer 123, so that the metal film 125 is bonded to and adheres to the semiconductor structure. In one embodiment of the present disclosure, the bonding layer is an adhesive, such as a polyimide or an epoxy, or a solder such as AuSn, AuGe, PbSn, or SnAgCu. The solder may be a eutectic solder.

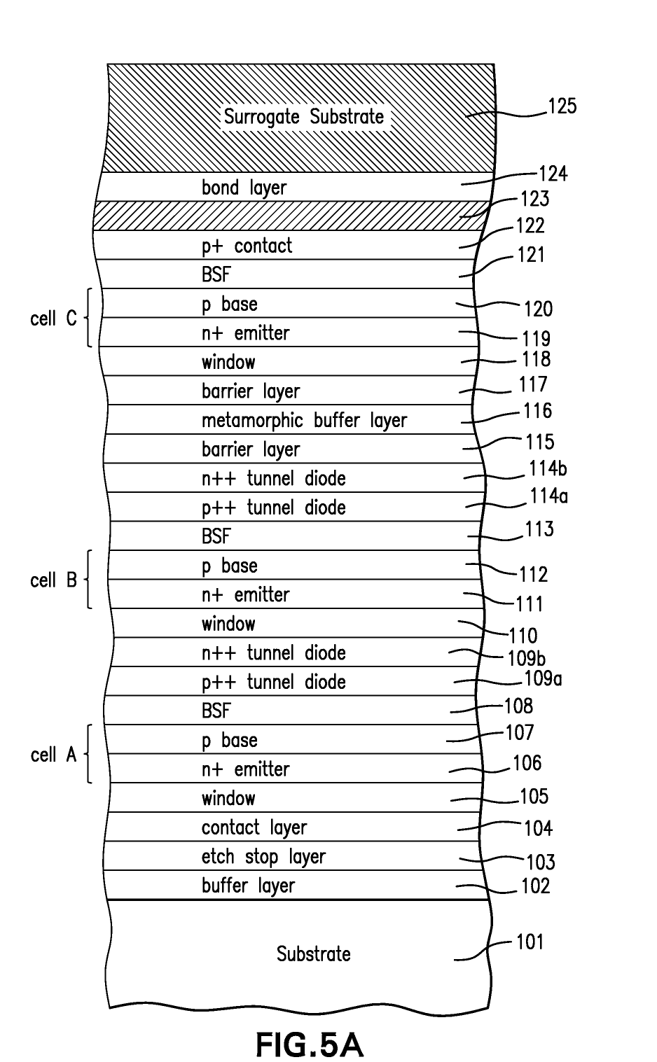

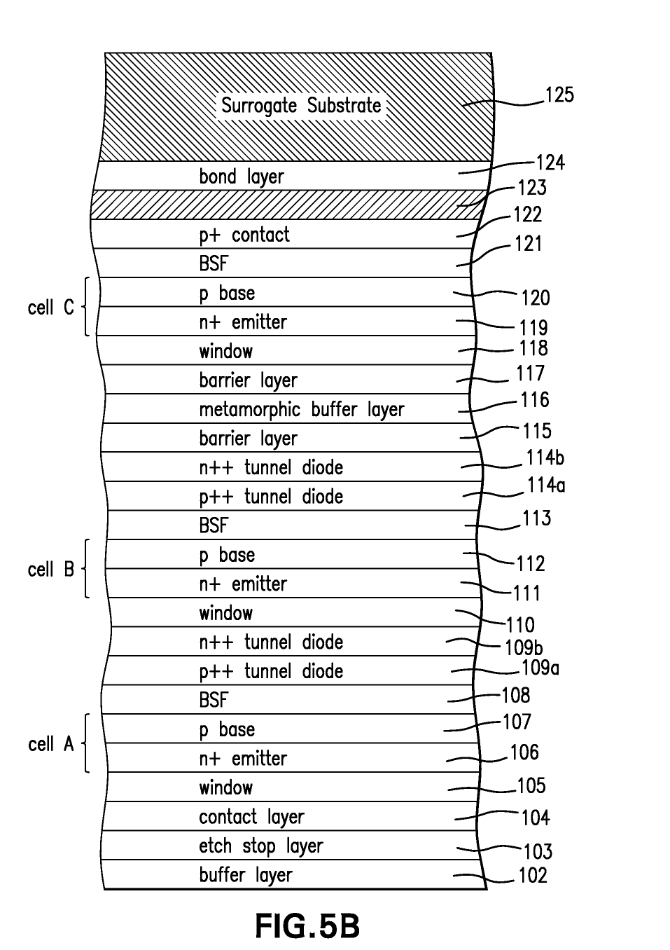

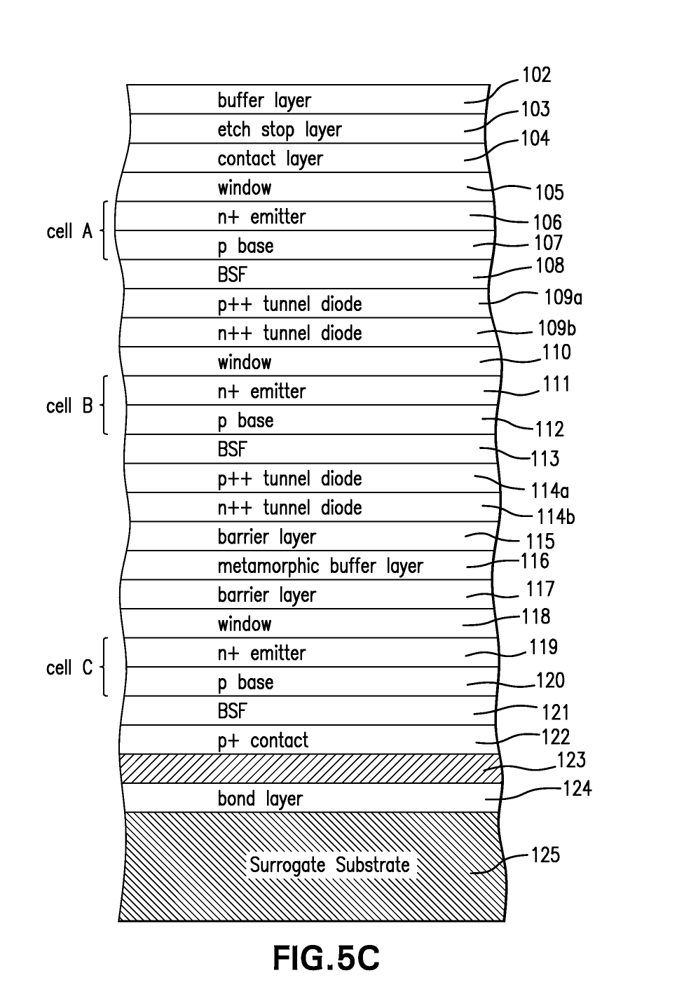

FIG. 5A is a cross-sectional view of the solar cell of FIG. 4 after the next process step in which a surrogate substrate 127 is attached to the top surface of the metallic film 125 using a temporary bonding adhesive 126. By “temporary” is meant that the adhesive can subsequently be removed as part of the fabrication process, e.g. by application of a suitable solvent, thereby freeing the surrogate substrate 127. The proper choice of the temporary adhesive 126 is critical, since the semiconductor structure with the surrogate substrate 127 will undergo a number of processing steps, including some (such as ARC deposition) at temperature above 250 degrees C., which may affect the effectiveness and stability of the temporary adhesive 126.

In some embodiments, the surrogate substrate 127 is glass, as described in U.S. patent application Ser. No. 13/547,334 filed Jul. 12, 2012 noted above. Alternatively, the surrogate substrate 127 may be sapphire, GaAs, Ge or Si, or other suitable material. In such alternative embodiments, the surrogate substrate 127 may be about 40 mils in thickness, and in the case of embodiments in which the surrogate substrate 127 is to be removed, it may be perforated with holes about 1 mm in diameter, spaced 4 mm apart, to aid in subsequent removal of the temporary adhesive 126 and the surrogate substrate 127.

FIG. 5B is a cross-sectional view of the solar cell of FIG. 5A after the next process step in which the original growth substrate 101 is removed. In some embodiments, the substrate 101 may be removed by a sequence of lapping, grinding and/or etching steps in which the substrate 101, and the buffer layer 103 are removed. The choice of a particular etchant is growth substrate dependent. In other embodiments, the substrate may be removed by a lift-off process such as described in U.S. patent application Ser. No. 12/367,991, filed Feb. 9, 2009, hereby incorporated by reference.

FIG. 5C is a cross-sectional view of the solar cell of FIG. 5B with the orientation with the surrogate substrate 127 being at the bottom of the Figure. Subsequent Figures in this application will assume such orientation.

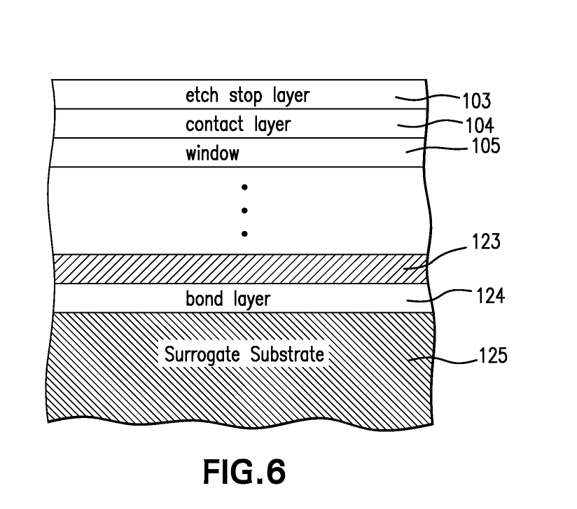

FIG. 6 is a simplified cross-sectional view of the solar cell of FIG. 5C depicting just a few of the top layers and lower layers over the surrogate substrate 127, with the orientation with the surrogate substrate 127 being at the bottom of the Figure. Subsequent Figures in this application will assume such orientation.

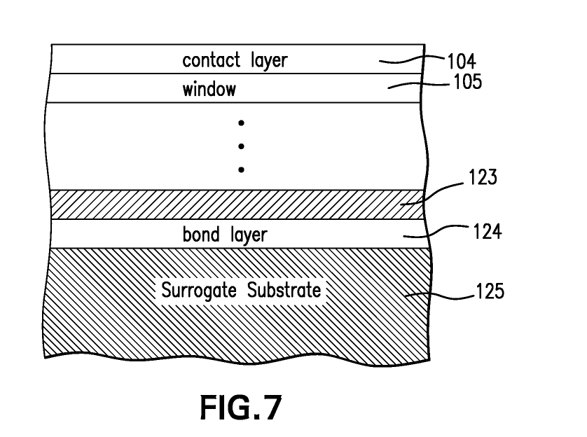

FIG. 7 is a cross-sectional view of the solar cell of FIG. 6 after the next process step in which the etch stop layer 103 is removed by a HCl/H₂O solution.

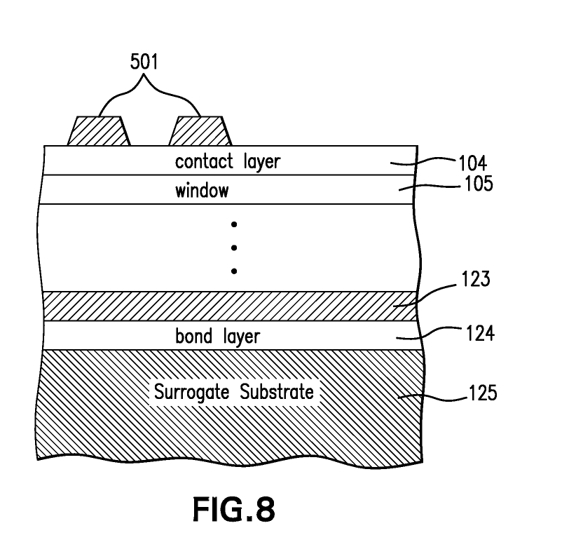

FIG. 8 is a cross-sectional view of the solar cell of FIG. 7 after the next sequence of process steps in which a photoresist mask (not shown) is placed over the contact layer 104 to form the grid lines 501. As will be described in greater detail below, the grid lines 501 are deposited via evaporation and lithographically patterned and deposited over the contact layer 104. The mask is subsequently lifted off to form the finished metal grid lines 501 as depicted in the Figures.

As more fully described in U.S. patent application Ser. No. 12/218,582 filed Jul. 18, 2008, hereby incorporated by reference, the grid lines 501 are preferably composed of the sequence of layers Pd/Ge/Ti/Pd/Au, although other suitable sequences and materials may be used as well.

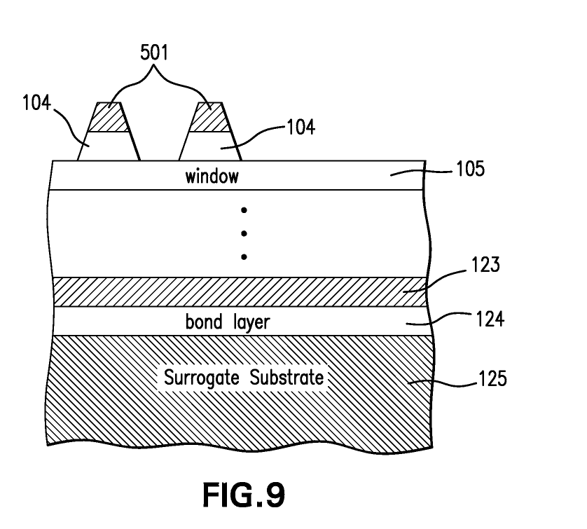

FIG. 9 is a cross-sectional view of the solar cell of FIG. 8 after the next process step in which the grid lines are used as a mask to etch down the surface to the window layer 105 using a citric acid/peroxide etching mixture.

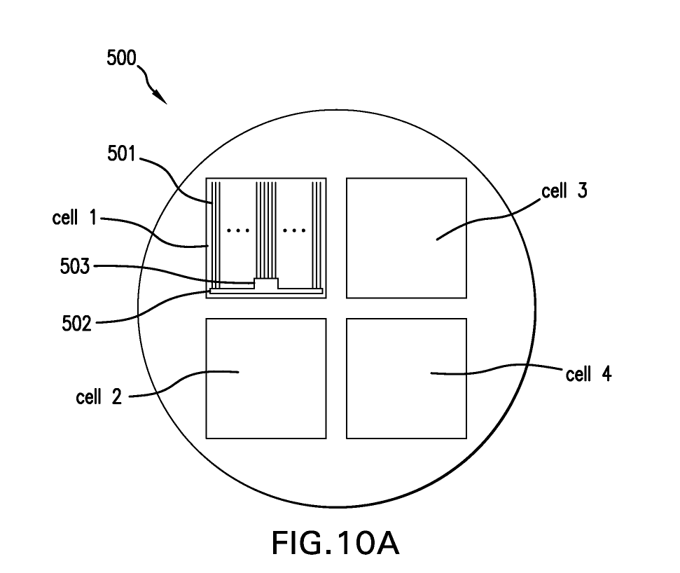

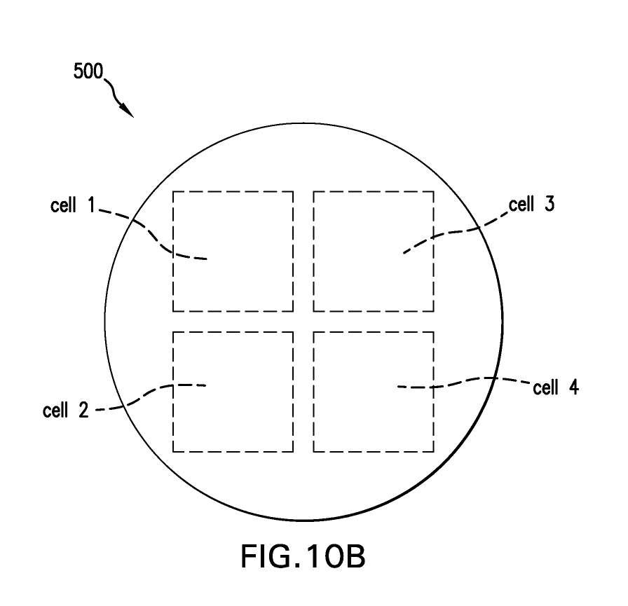

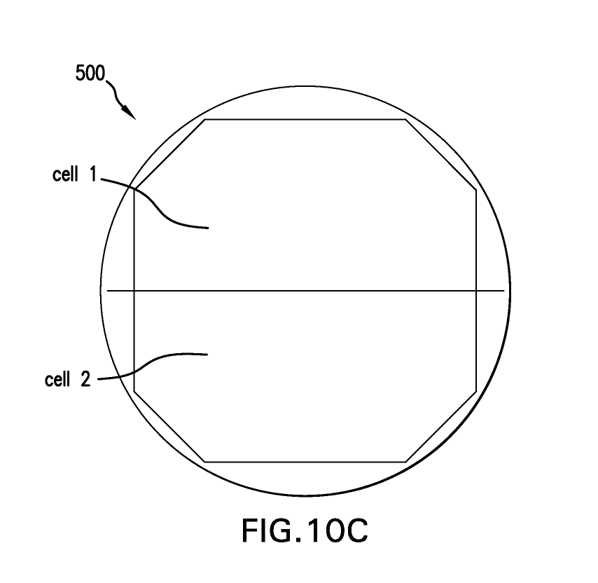

FIG. 10A is a top plan view of a 100 mm (or 4 inch) wafer in which four solar cells are implemented. The depiction of four cells is for illustration purposes only, and the present invention is not limited to any specific number of cells per wafer.

In each cell there are grid lines 501 (more particularly shown in cross-section in FIG. 9), an interconnecting bus line 502, and a contact pad 503. The geometry and number of grid and bus lines and the contact pad are illustrative and the present invention is not limited to the illustrated embodiment.

FIG. 10B is a bottom plan view of the wafer of FIG. 10A in which the four solar cells are fabricated, with the location of the cells shown in dotted lines;

FIG. 10C is a top plan view of a 100 mm (or 4 inch) wafer in which two solar cells are implemented. In this depicted example, each solar cell has an area of 27.5 cm² and a power/weight ratio (after separation from the growth and surrogate substrates) of 549 mW/g, where a 50 micron thick Kovar substrate is utilized.

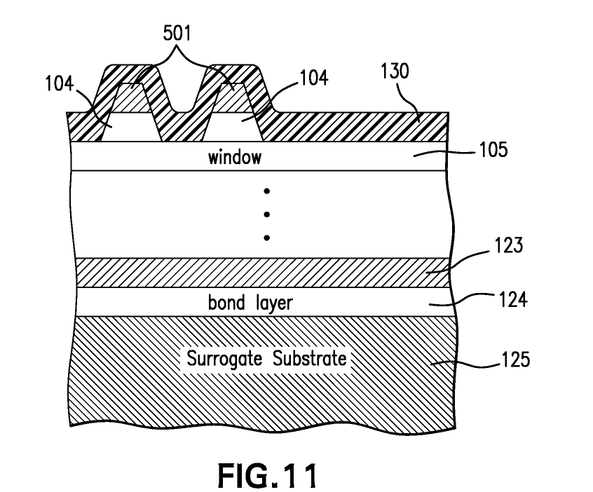

FIG. 11 is a cross-sectional view of the solar cell of FIG. 9 after the next process step in which an antireflective (ARC) dielectric coating layer 130 is applied over the entire surface of the “top” side of the wafer with the grid lines 501.

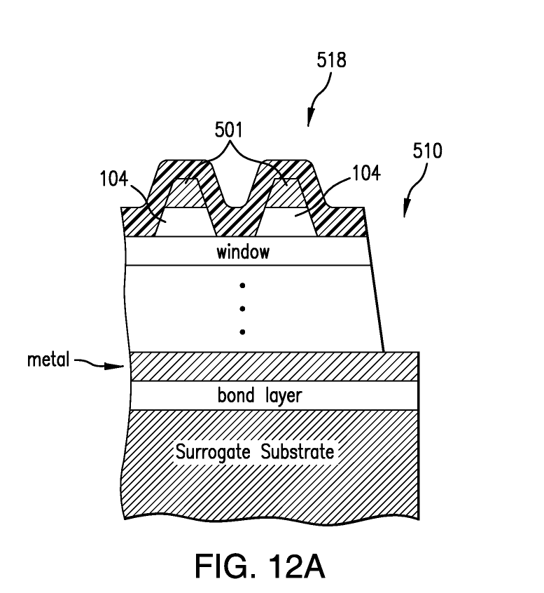

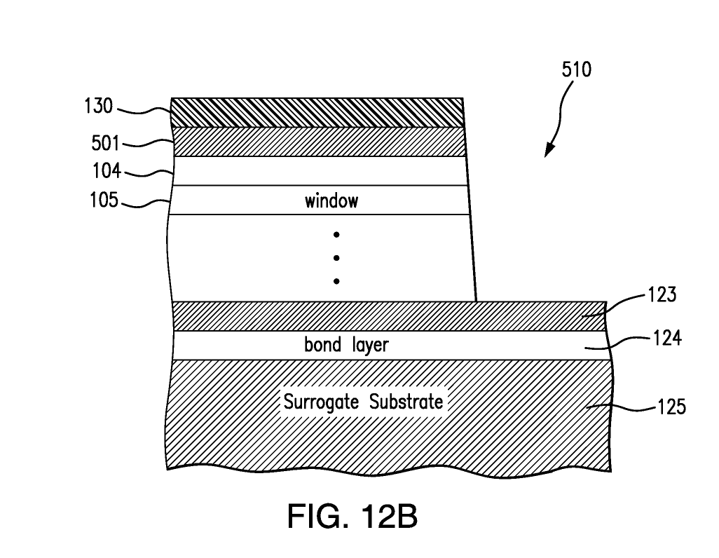

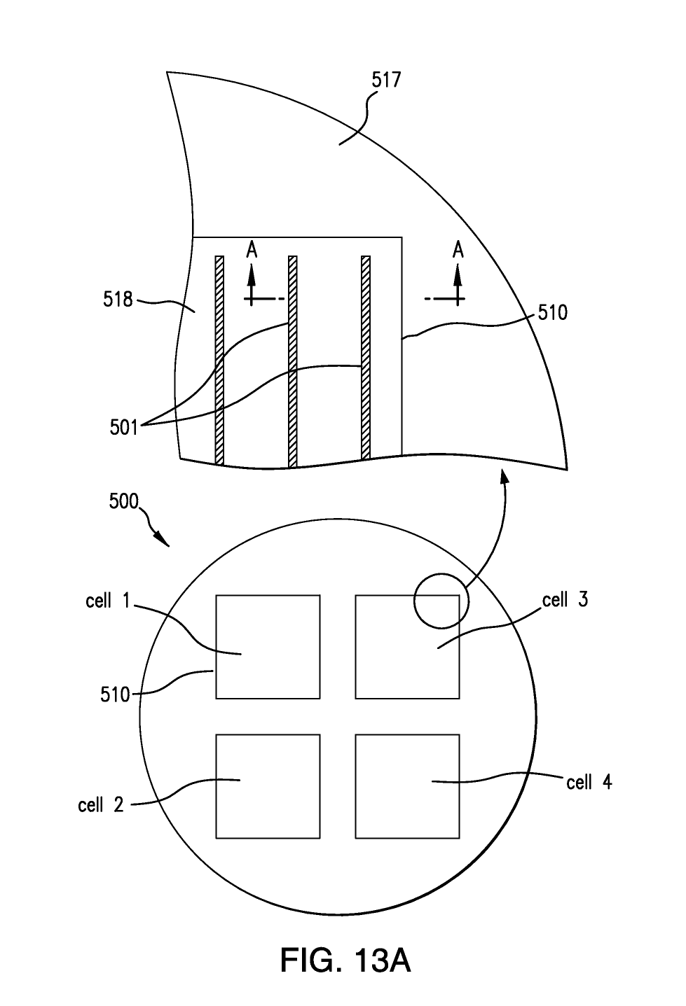

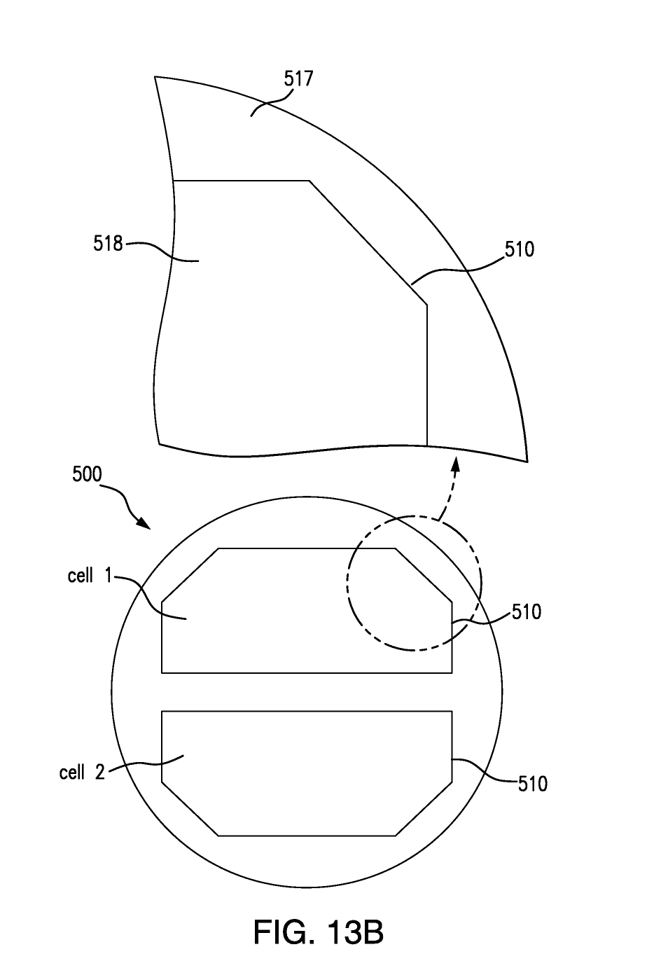

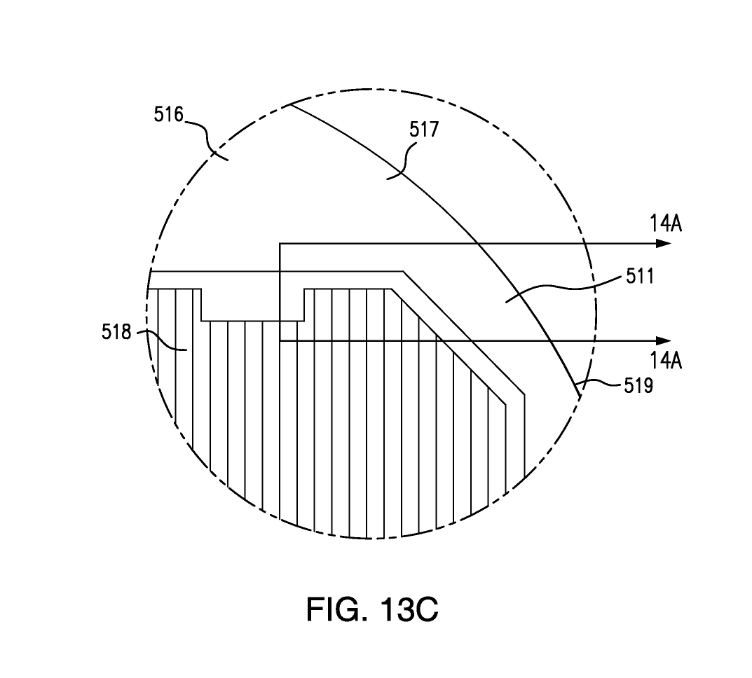

FIG. 12A is a cross-sectional view of the solar cell of FIG. 11 after the next process step according to some embodiments of the present invention in an annular channel 510, or portion of the semiconductor structure are etched down to the metal layer 123 using phosphide and arsenide etchants. This channel 510 defines a peripheral boundary between the cell and the rest of the wafer, and leaves a mesa structure which constitutes the solar cell. The cross-section depicted in FIG. 12A is that as seen from the A-A plane shown in FIG. 13.

FIG. 12B is a cross-sectional view of the solar cell of FIG. 11 similar to that of FIG. 12A, but in a view longitudinally along a grid line.

FIG. 13A is a top plan view of the wafer of FIG. 10A, depicting the channel 510 etched around the periphery of each cell which were shown in cross-section in FIG. 12B.

FIG. 13B is a top plan view of the wafer of FIG. 10C depicting the channel 510 etched around the periphery of each cell which were shown in cross-section in FIG. 12B.

FIG. 13C is a top plan view of the wafer of FIG. 13B, after the next process steps in which a portions of the ARC layer 130 are removed to provide access to the grid metal layer 501 for contact pads.

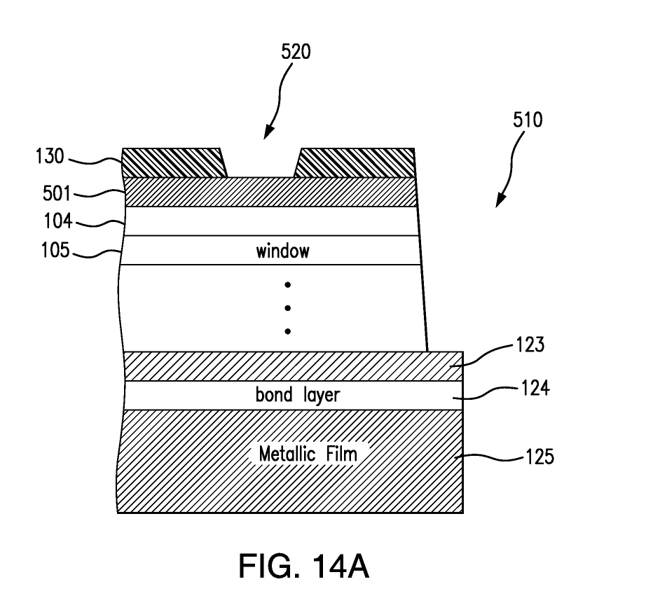

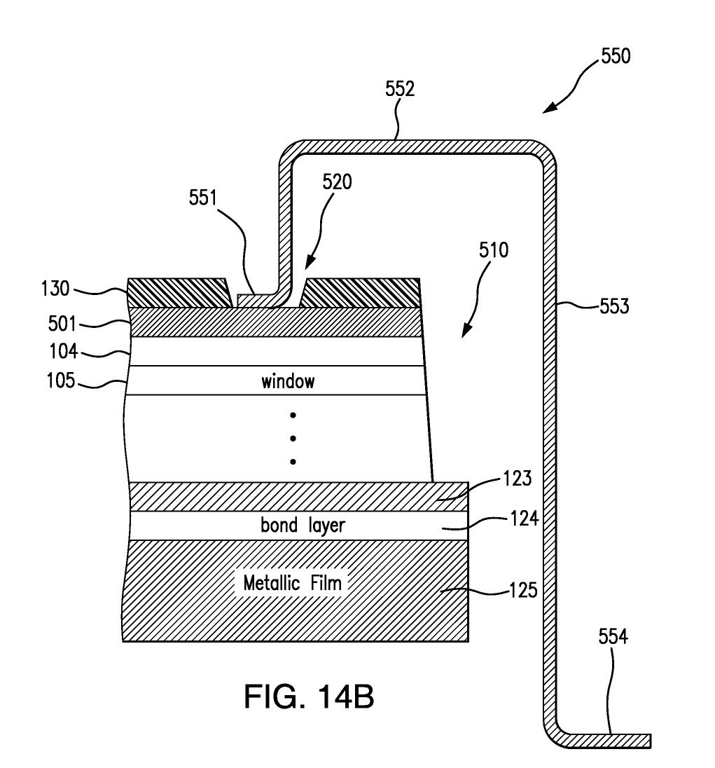

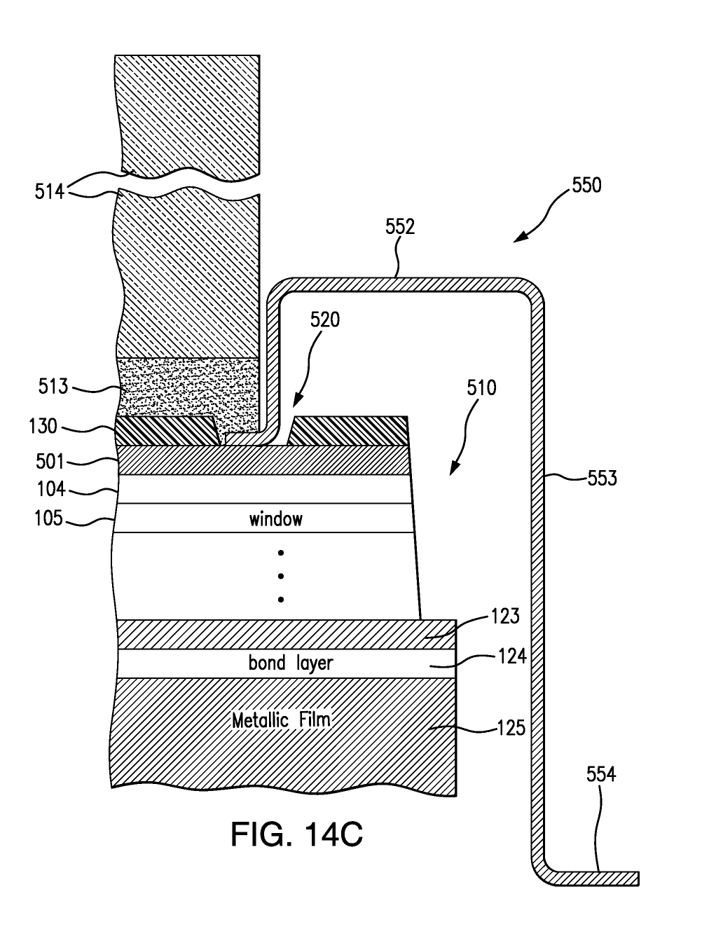

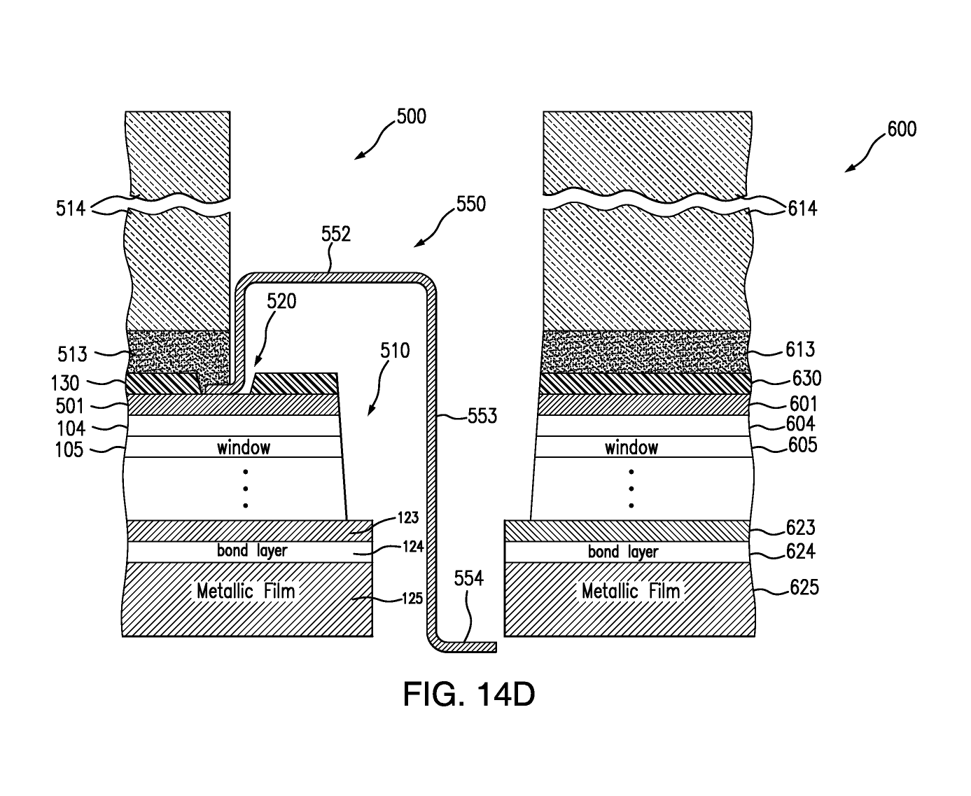

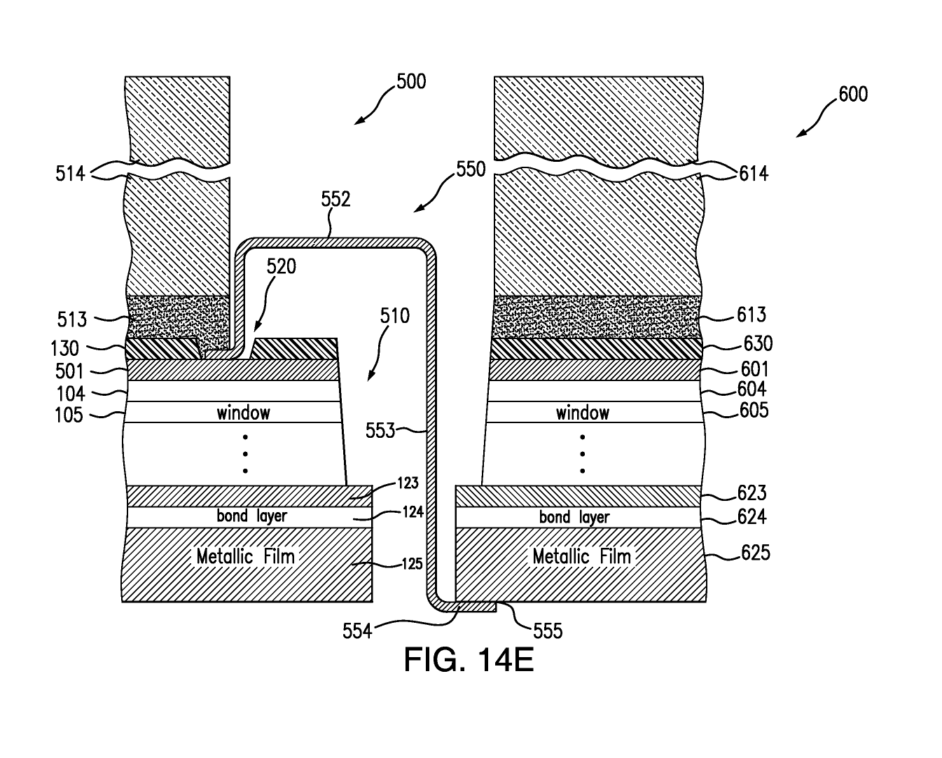

FIG. 14A is a cross-sectional view of the solar cell of FIG. 13C though the 14A-14A plane. A contact pad 520 to the grid metal layer 501 is depicted.

FIG. 14B is a cross-sectional view of the solar cell of FIG. 14A following the removal of the surrogate substrate 127. The surrogate substrate 127 is removed by the use of the Wafer Bond solvent, or other techniques. As noted above, the surrogate substrate 127 includes perforations over its surface that allow the flow of solvent through the surrogate substrate 127 to permit its lift off. The surrogate substrate 127 may be reused in subsequent wafer processing operations.

FIG. 14C further depicts the attachment of an interconnection member 550 to the metal contact pad 520. The interconnection member 550 is a planar rectangular clip having a first flat end-portion 551 welded to the metal contact layer 501, a second portion 552 connected to the first end-portion 551 and extending above the surface of the solar cell, and a third portion 553 connected to the second portion 552 and being serpentine in shape, and flat second end-portion 554 extending below the bottom of the solar cell and designed and oriented to be welded to the bottom metal contact of an adjacent solar cell.

FIG. 14D is a cross-sectional view of the solar cell of FIG. 14C after the next process step of attachment of a cover glass 514 to the top of the solar cell by an adhesive 513. The cover glass 514 is typically about 4 mils thick. Although the use of a cover glass is desirable for many environmental conditions and applications, it is not necessary for all implementations, and additional layers or structures may also be utilized for providing additional support or environmental protection to the solar cell.

FIG. 14E is a cross-sectional view of the solar cell of FIG. 14D, which is now designated as cell 500, after the next process step of alignment with the edge of an adjacent similar solar cell 600, in the process of fabricating an interconnected array or string of solar cells. The similar solar cell 600 includes layers 630, 601, 604, 605 through 623, 624 and 625 similar to layers 130, 501, 104, 105 through 123, 124 and 125 respectively of solar cell 500. A cover glass 614 is attached by adhesive 613 to the solar cell 600 similar to that in solar cell 500.

FIG. 14F is a cross-sectional view of the solar cell of FIG. 14E after the next process step of welding the end portion 554 of interconnection member 550 of the first solar cell 500 to the end portion 555 of metallic supporting film 625 of the second solar cell.

In some implementations, the metallic film 125 is a solid metallic foil with adjoining layers of a polyimide material, such as Kapton™. More generally, the material may be a nickel-cobalt ferrous alloy material, or a nickel iron alloy material.

In other implementations, which are unifacial rather than bifacial implementations, the metallic film comprises a metallic layer deposited on a surface of a Kapton or polyimide material.

In some implementations, the semiconductor solar cell has a thickness of less than 50 microns, and the metallic flexible film 150 has a thickness of approximately 50 microns, or more generally, between 0.001 and 0.01 inches. An alternative substrate implementation would be 0.002″ Kapton film plus 0.0015″ adhesive/0.002″ Mo Foil/0.002″ Kapton film plus 0.0015″ adhesive for a total thickness of 0.009″. However the Kapton film can be as thin as 0.001″ and as thick as 0.01″. The adhesive can be as thin as 0.0005″ and as thick as 0.005″. The Mo foil can be as thin as 0.001″ and as thick as 0.005″.

In some implementations, the metallic flexible film 150 comprises a molybdenum layer, and in some implementations, the metal electrode layer 123 also includes molybdenum.

In some implementations, the metal electrode layer 123 includes a Mo/Ti/Ag/Au, Ti/Au/Mo, Ti/Au/Ag/Au/Ti/Mo/Ti, or Ti/Au/Ti/Mo/Ni/Au sequence of layers.

In some implementations, the metal electrode layer 123 includes a sequence of layers including Ti/Au/Ag/Au or Ti/Mo/Ni/Au, among other sequences of layers in the metal electrode layer.

FIG. 15 is a graph of a doping profile in the emitter and base layers in one or more subcells of some embodiments of the inverted metamorphic multijunction solar cell of the present invention. The various doping profiles within the scope of the present invention, and the advantages of such doping profiles are more particularly described in U.S. Pat. No. 7,727,795, herein incorporated by reference. The doping profiles depicted herein are merely illustrative, and other more complex profiles may be utilized as would be apparent to those skilled in the art without departing from the scope of the present invention.

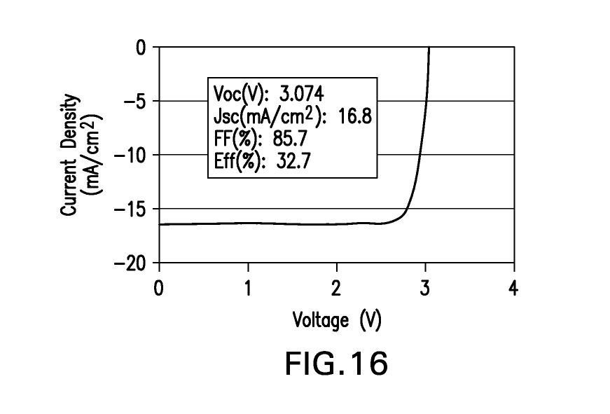

FIG. 16 is a graph that depicts the current and voltage characteristics of the solar cell that is representative of inverted metamorphic multijunction solar cells disclosed in the related applications noted above and according to the present disclosure under simulated AM0 illumination. The solar cell has an open circuit voltage (V_{oc}) of approximately 3.074 volts, a short circuit current of approximately 16.8 mA/cm², a fill factor of approximately 85.7%, and an efficiency of 32.7%.

FIG. 17 is a graph representing the Al, Ga and In mole fractions versus the lattice constant in a AlGaInAs material system that is necessary to achieve a constant 1.5 eV band gap.

FIG. 18 is a diagram representing the relative concentration of Al, In, and Ga in an AlGaInAs material system needed to have a constant band gap with various designated values (ranging from 0.4 eV to 2.1 eV) as represented by curves on the diagram. The range of band gaps of various GaInAlAs materials is represented as a function of the relative concentration of Al, In, and Ga. This diagram illustrates how the selection of a constant band gap sequence of layers of GaInAlAs used in the metamorphic layer may be designed through the appropriate selection of the relative concentration of Al, In, and Ga to meet the different lattice constant requirements for each successive layer. Thus, whether 1.5 eV or 1.1 eV or other band gap value is the desired constant band gap, the diagram illustrates a continuous curve for each band gap, representing the incremental changes in constituent proportions as the lattice constant changes, in order for the layer to have the required band gap and lattice constant.

FIG. 19 is a graph that further illustrates the selection of a constant band gap sequence of layers of GaInAlAs used in the metamorphic layer by representing the Ga mole fraction versus the Al to In mole fraction in GaInAlAs materials that is necessary to achieve a constant 1.5 eV band gap.

It will be understood that each of the elements described above, or two or more together, also may find a useful application in other types of constructions differing from the types of constructions described above.

Although some of the embodiments of the present invention utilizes a vertical stack of three subcells, the present invention can apply to stacks with fewer or greater number of subcells, i.e. two junction cells, four junction cells, five junction cells, etc. as more particularly described in U.S. Pat. No. 8,236,600 based on application Ser. No. 12/267,812 filed Nov. 10, 2008. In the case of four or more junction cells, the use of more than one metamorphic grading interlayer may also be utilized, as more particularly described in U.S. patent application Ser. No. 12/271,192 filed Nov. 14, 2008.

In addition, although in some embodiments the solar cell is configured with top and bottom electrical contacts, the subcells may alternatively be contacted by means of metal contacts to laterally conductive semiconductor layers between the subcells. Such arrangements may be used to form 3-terminal, 4-terminal, and in general, n-terminal devices. The subcells can be interconnected in circuits using these additional terminals such that most of the available photogenerated current density in each subcell can be used effectively, leading to high efficiency for the multijunction cell, notwithstanding that the photogenerated current densities are typically different in the various subcells.

As noted above, embodiments of the present invention may utilize an arrangement of one or more, or all, homojunction cells or subcells, i.e., a cell or subcell in which the p-n junction is formed between a p-type semiconductor and an n-type semiconductor both of which have the same chemical composition and the same band gap, differing only in the dopant species and types, and one or more heterojunction cells or subcells. Subcell A, with p-type and n-type InGaP is one example of a homojunction subcell. Alternatively, as more particularly described in U.S. patent application Ser. No. 12/023,772 filed Jan. 31, 2008, the present invention may utilize one or more, or all, heterojunction cells or subcells, i.e., a cell or subcell in which the p-n junction is formed between a p-type semiconductor and an n-type semiconductor having different chemical compositions of the semiconductor material in the n-type regions, and/or different band gap energies in the p-type regions, in addition to utilizing different dopant species and type in the p-type and n-type regions that form the p-n junction.

In some embodiments, a thin so-called “intrinsic layer” may be placed between the emitter layer and base layer of some subcells, with the same or different composition from either the emitter or the base layer. The intrinsic layer may function to suppress minority-carrier recombination in the space-charge region by minimizing interdiffusion of the n-type and p-type dopants on either side of the junction. Similarly, either the base layer or the emitter layer may also be intrinsic or not-intentionally-doped (“NID”) over part or all of its thickness. Some such configurations are more particularly described in U.S. patent application Ser. No. 12/253,051 filed Oct. 16, 2008.

The composition of the window or BSF layers may utilize other semiconductor compounds, subject to lattice constant and band gap requirements, and in some embodiments may include AlInP, AlAs, AlP, AlGaInP, AlGaAsP, AlGaInAs, AlGaInPAs, GaInP, GaInAs, GaInPAs, AlGaAs, AlInAs, AlInPAs, GaAsSb, AlAsSb, GaAlAsSb, AlInSb, GaInSb, AlGaInSb, AlN, GaN, InN, GaInN, AlGaInN, GaInNAs, AlGaInNAs, ZnSSe, CdSSe, and similar materials, and still fall within the spirit of the present invention.

Although the invention has been illustrated and described as embodied in an inverted metamorphic multijunction solar cell, it is not intended to be limited to the details shown, since various modifications and structural changes may be made without departing in any way from the spirit of the present invention.

Thus, while the description of this invention has focused primarily on solar cells or photovoltaic devices, persons skilled in the art know that other optoelectronic devices, such as, thermophotovoltaic (TPV) cells, photodetectors and light-emitting diodes (LEDs) are very similar in structure, physics, and materials to photovoltaic devices with some minor variations in doping and the minority carrier lifetime. For example, photodetectors can be the same materials and structures as the photovoltaic devices described above, but perhaps more lightly-doped for sensitivity rather than power production. On the other hand LEDs can also be made with similar structures and materials, but perhaps more heavily-doped to shorten recombination time, thus radiative lifetime to produce light instead of power. Therefore, this invention also applies to photodetectors and LEDs with structures, compositions of matter, articles of manufacture, and improvements as described above for photovoltaic cells.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and, therefore, such adaptations should and are intended to be comprehended within the meaning and range of equivalence of the following claims.

1. A method of manufacturing a mounted solar cell comprising:
providing a first substrate having a surface area of at least 50 square centimeters;
depositing on the entire surface of the first substrate a sequence of layers of semiconductor material to form a multijunction solar cell using a MOCVD reactor;
depositing a metal electrode layer on the surface of the layers of semiconductor material;
attaching a metallic flexible film comprising a nickel-cobalt ferrous alloy material, or a nickel iron alloy material, directly to the surface of the metal electrode layer of the semiconductor solar cell, wherein the coefficient of thermal expansion of the semiconductor body closely matches the coefficient of thermal expansion of the metallic film and the metal electrode layer so that during subsequent processing and temperature cycling, the wafer bow and stress in the layers of semiconductor material are minimized;
removing the first substrate;
depositing and lithographically patterning a plurality of metal grid lines disposed on the top surface of the first solar subcell, including at least one metal contact pad electrically connected to said grid lines and disposed adjacent to a first peripheral edge of said first solar sub cell;
depositing an anti-reflection coating layer over the metal grid lines and the exposed top surface of the solar cell; and
attaching a discrete inter-cell electrical interconnection member to the metal contact pad.

2. A method as defined in claim 1, the attaching step of the metallic film is performed by one of adhesive bonding, metal sputtering, metal evaporation or soldering.

3. A method as defined in claim 2, wherein the adhesive bonding step utilizes electrically conductive epoxy; Ag or C-loaded polymide/or B-stage epoxies.

4. A method as defined in claim 2, wherein the soldering step utilizes AuGe, AuSn, PbSn, or SnAgCu (SAC)-solders.

5. A method as defined in claim 1, wherein the metallic film is a solid metallic foil, or a metallic layer deposited on a surface of a polyimide material.

6. A method as defined in claim 1, further comprising bonding a surrogate substrate over the metallic flexible film using a temporary adhesive, and subsequently removing said first substrate by grinding the first substrate to remove over 80% of its thickness, followed by an etching step to remove the remaining portion of the first substrate.

7. A method as defined in claim 1, wherein the discrete interconnection member is a planar rectangular clip having a first end-portion welded to the metal contact layer, a second portion connected to the first end-portion and extending above the surface of the solar cell, and a third portion connected to the second portion and being serpentine in shape, and further comprising subsequently attaching a cover glass over the side of the solar cell having the metal grid lines and the attached interconnection member,

8. A method as defined in claim 7, further comprising welding the third portion of the metal interconnection member to a terminal of opposite polarity of an adjacent solar cell to thereby form an electrical series connection.

9. A method as defined in claim 1, wherein the metal electrode layer has a coefficient of thermal expansion within a range of 0 to 15 ppm per degree Kelvin different from that of the adjacent semiconductor material of the semiconductor solar cell.

10. A method as defined in claim 1, wherein the coefficient of thermal expansion of the metal electrode layer is in the range of 5 to 7 ppm per degree Kelvin.

11. A method as defined in claim 1, wherein the metal electrode layer includes molybdenum.

12. A method as defined in claim 1, wherein the metal electrode layer includes a sequence of layers including Ti/Au/Ag/Au or Ti/Mo/Ni/Au, among other sequences of layers in the metal electrode layer.

13. A method as defined in claim 1, wherein the attaching step of the interconnection member is performed by welding.

14. A method for fabricating a solar cell array as defined in claim 1, wherein the metal interconnection member is composed of molybdenum, a nickel-cobalt ferrous alloy, or a nickel iron alloy material.

15. The method as defined in claim 1, wherein the step of depositing a sequence of layers comprises:
forming a first subcell comprising a first semiconductor material with a first band gap and a first lattice constant;
forming a second subcell comprising a second semiconductor material with a second band gap and a second lattice constant, wherein the second band gap is less than the first band gap and the second lattice constant is greater than the first lattice constant; and
forming a lattice constant transition material positioned between the first subcell and the second subcell, said lattice constant transition material having a lattice constant that changes gradually from the first lattice constant to the second lattice constant.

16. A method as defined in claim 15, wherein said transition material is composed of any of the As, N, Sb based III-V compound semiconductors subject to the constraints of having the in-plane lattice parameter greater or equal to that of the first subcell and less than or equal to that of the second subcell, and having a band gap energy greater than that of the first subcell, and the band gap of the transition material remains constant throughout its thickness.

17. A method as defined in claim 15, wherein the lattice constant transition material is composed of (InₓGa₁₋ₓ)_{y}Al_{1-y}As with 0<x<1, 0<y<1, and x and y selected such that the band gap of the transition material remains constant throughout its thickness.

18. A method as defined in claim 15, wherein said first subcell is composed of an GaInP, GaAs, GaInAs, GaAsSb, or GaInAsN emitter region and an GaAs, GaInAs, GaAsSb, or GaInAsN base region, and the second subcell is composed of an InGaAs base and emitter regions.

19. A method of forming a solar cell as defined in claim 1, wherein the step of depositing a sequence of layers comprises:
forming a first subcell comprising a first semiconductor material with a first band gap and a first lattice constant;
forming a second subcell comprising a second semiconductor material with a second band gap and a second lattice constant, wherein the second band gap is less than the first band;
forming a grading interlayer over the second subcell, and having a third band gap greater than said second band gap, and having a lattice constant that changes gradually from the second lattice constant to a third lattice constant; and
forming a third subcell comprising a third semiconductor material with a fourth band gap and a third lattice constant, wherein the fourth band gap is less than the second band gap and the third subcell is lattice mismatched with respect to the second subcell.

20. A multijunction solar cell comprising:
a top first solar subcell having a first band gap;
a middle second solar subcell disposed directly adjacent to said first subcell and having a second band gap smaller than said first band gap;
a grading interlayer disposed directly adjacent to said second subcell and having a third band gap greater than second band gap, said grading interlayer being deposited using an MOCVD process;
a bottom third solar subcell disposed and directly adjacent to said grading interlayer and being lattice mismatched with respect to said middle second subcell, and having a fourth band gap smaller than said second band gap;
a plurality of metal grid lines disposed on the top surface of the first solar subcell, including at least one metal contact pad electrically connected to said grid lines and disposed adjacent to a first peripheral edge of said first solar subcell;
a metal contact layer adjacent to said third solar subcell for making an electrical contact to the third solar subcell;
a metallic supporting film deposed adjacent to the metal contact layer, the metallic film including a metallic layer deposited on a surface of a Kapton or polyimide material;
a cut-out extending from a second peripheral edge of the first solar subcell opposite from said first edge and along the top surface of the solar cell to the metal contact layer; and
a discrete metal interconnection member extending to the metal contact layer through the cut-out, the interconnection member having a first planar end-portion welded to the metal contact layer, a second portion connected to the first end-portion and extending through the cut-out and above the surface of the solar cell, and a third portion connected to the second portion and being serpentine in shape.
